(19) United States
(12) Patent Application Publication
(10) Pub. No.: US 2022/0337771 A1
(43) Pub. Date: Oct. 20, 2022

(54) CAMERA MODULE AND OPERATING METHOD OF CAMERA MODULE

(71) Applicant: SAMSUNG ELECTRONICS CO., LTD., SUWON-SI (KR)

(72) Inventors: JUNG BIN YUN, HWASEONG-SI (KR); KYUNGHO LEE, SUWON-SI (KR); EUN SUB SHIM, HWASEONG-SI (KR); TAESUB JUNG, HWASEONG-SI (KR)

(21) Appl. No.: 17/565,591

(22) Filed: Dec. 30, 2021

(30) Foreign Application Priority Data
Apr. 16, 2021 (KR) 10-2021-0049836

(51) Int. Cl. H04N 5/369; H04N 5/3745

(52) U.S. Cl. CPC H04N 5/36961; H04N 5/37455; H04N 5/36965

(57) ABSTRACT

A camera module includes pixels each including first to fourth sub-pixels, a row driver connected to the pixels through row lines, an analog-to-digital conversion circuit connected to the pixels through column lines and converting signals of the column lines into digital values, and a logic circuit. Each of the first to fourth sub-pixels includes a first region and a second region. Each of the first and second regions includes a photo detector. In response to the row driver activating signals of half or less of the photo detectors included in one pixel among the pixels, the analog-to-digital conversion circuit generates a first signal. The logic circuit generates an auto focus signal based on the first signal.

### CROSS-REFERENCE TO RELATED APPLICATIONS

This application claims priority under 35 U.S.C. § 119 to Korean Patent Application No. 10-2021-0049836 filed on Apr. 16, 2021, in the Korean Intellectual Property Office, the disclosure of which is incorporated by reference herein in its entirety.

### TECHNICAL FIELD

Embodiments of the present disclosure described herein relate to an electronic device, and more particularly, relate to a camera module performing auto focusing in a high dynamic range (HDR), and an operating method of the camera module.

### DISCUSSION OF RELATED ART

A camera module may generate image data indicating a target or scenery from the target. As the performance of mobile devices such as, for example, smartphones and tablet computers improves, camera modules may be employed in the mobile devices. Because image modules employed in the mobile devices generate image data, the image modules may be used to create image-based content.

To generate image data of an improved quality, a function of auto focusing may be implemented in the camera module. The auto focusing may include determining a focus corresponding to a target or scenery, based on signals generated from a photo detector(s) corresponding to a left eye from among photo detectors of an image sensor and signals generated from a photo detector(s) corresponding to a right eye from among the photo detectors.

### SUMMARY

Embodiments of the present disclosure provide a camera module that prevents a signal for auto focusing from being saturated, and an operating method of the camera module.

According to an embodiment, a camera module includes a pixel array that includes pixels arranged in a row, wherein each of the pixels includes a first sub-pixel, a second sub-pixel, a third sub-pixel, and a fourth sub-pixel, a row driver that is connected to the pixels through row lines, an analog-to-digital conversion circuit that is connected to the pixels through column lines and converts signals of the column lines into digital values, and a logic circuit. Each of the first sub-pixel, the second sub-pixel, the third sub-pixel, and the fourth sub-pixel includes a first region and a second region. Each of the first region and the second region includes a photo detector. In response to the row driver activating signals of half or less of the photo detectors included in one pixel among the pixels, the analog-to-digital conversion circuit generates a first signal. In response to the row driver performing binning on signals of the photo detectors included in the one pixel among the pixels, the analog-to-digital conversion circuit generates a second signal. The logic circuit generates an auto focus signal based on the first signal.

According to an embodiment, an operating method of a camera module which includes a plurality of pixels, wherein the plurality of pixels includes a plurality of sub-pixels and each of the plurality of sub-pixels includes a plurality of photo detectors, includes receiving a signal from half or less of the photo detectors of one pixel among the plurality of pixels, and in response to a level of the signal being smaller than a first threshold, increasing the number of the photo detectors from which the signal is received. Auto focusing is performed based on the signal.

According to an embodiment, a camera module includes a first photo detector, a second photo detector, a third photo detector, and a fourth photo detector that are arranged in a first row, a fifth photo detector, a sixth photo detector, a seventh photo detector, and an eighth photo detector that are arranged in a second row, a row driver that connects half or less of the first to eighth photo detectors with a floating diffusion node in a first time interval, connects the first to eighth photo detectors with the floating diffusion node in a second time interval, and connects the first to eighth photo detectors with the floating diffusion node in a third time interval, and an analog-to-digital conversion circuit that generates a first signal from the floating diffusion node in the first time interval, generates a second signal from the floating diffusion node in the second time interval, and generates a third signal from the floating diffusion node in the third time interval. The first signal is used in auto focusing.

### BRIEF DESCRIPTION OF THE DRAWINGS

The above and other objects and features of the present disclosure will become more apparent by describing in detail embodiments thereof with reference to the accompanying drawings, in which:

FIG. 1 illustrates a camera module according to an embodiment of the present disclosure.

FIG. 2 illustrates an example of a pixel according to an embodiment of the present disclosure.

FIG. 3 illustrates a first example in which first to third pixels belonging to the same row are connected to lines of a corresponding row line.

FIG. 4 illustrates an example in which a camera module captures image data of pixels in one row based on a wire structure of FIG. 3.

FIG. 5 illustrates a second example in which first to third pixels belonging to the same row are connected to lines of a corresponding row line.

FIG. 6 illustrates an example in which a camera module captures image data of pixels in one row based on a wire structure of FIG. 5.

FIG. 7 illustrates various cases of a third example in which a digital HCG auto focus signal is generated based on a wire structure of FIG. 5.

FIGS. 8 to 14 illustrate third to ninth examples in which first to third pixels belonging to the same row are connected to lines of a corresponding row line.

FIG. 15 illustrates a 23rd case in which a digital HCG auto focus signal is generated based on a wire structure of FIG. 14.

FIG. 16 illustrates an example in which a camera module captures image data of pixels in one row based on one of wire structures of FIGS. 5 and 8 to 14.

FIG. 17 illustrates an example of an operating method of a camera module implemented in a wire structure of FIG. 5.

FIG. 18 is a block diagram of an electronic device including a multi-camera module.

FIG. 19 is a detailed block diagram of a camera module of FIG. 18.

### DETAILED DESCRIPTION

Embodiments of the present disclosure will be described more fully hereinafter with reference to the accompanying drawings. Like reference numerals may refer to like elements throughout the accompanying drawings.

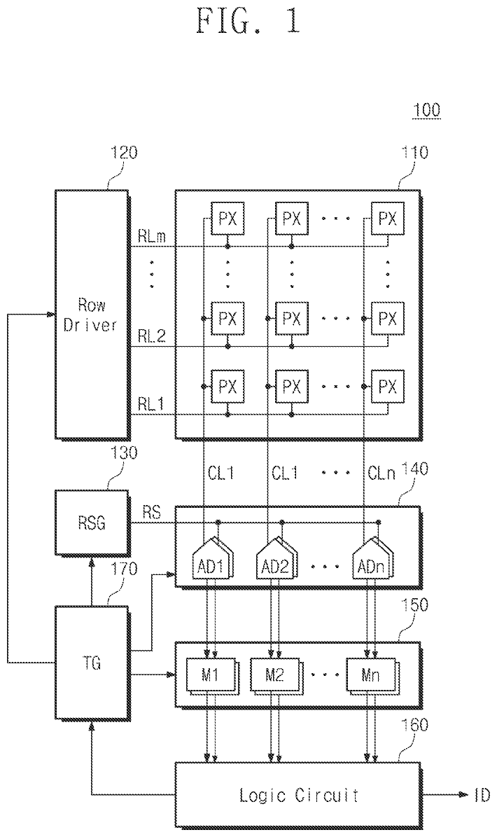

FIG. 1 illustrates a camera module 100 according to an embodiment of the present disclosure. Referring to FIG. 1, the camera module 100 may include a pixel array 110, a row driver 120, a ramp signal generator 130 (RSG), an analog-to-digital conversion circuit 140, a memory circuit 150, a logic circuit 160, and a timing generator 170 (TG).

The pixel array 110 may include a plurality of pixels PX arranged in rows and columns in the form of a matrix. Each of the plurality of pixels PX may include a photo detector. For example, the photo detector may include a photo diode, a photo transistor, a photo gate, a pinned photodiode, etc. Each of the plurality of pixels may sense a light by using the photo detector and may convert the amount of the sensed light into an electrical signal, for example, a voltage or a current.

A color filter array (CFA) and lenses may be stacked on the pixel array 110. The color filter array may include red (R) filters, green (G) filters, and blue (B) filters. Two or more different color filters may be disposed at each of the plurality of pixels PX. For example, at least one blue color filter, at least one red color filter, and at least two green color filters may be disposed at each of the plurality of pixels PX in an embodiment.

The row driver 120 may be connected to rows of the pixels PX of the pixel array 110 through first to m-th row lines RL1 to RLm (m being a positive integer). The row driver 120 may decode an address and/or a control signal generated by the timing generator 170. Depending on a result of the decoding, the row driver 120 may sequentially drive the first to m-th row lines RL1 to RLm of the pixel array 110 and may select a selected row line with a specific voltage. For example, the row driver 120 may drive a selected row line with a voltage appropriate to sense a light.

Each of the first to m-th row lines RL1 to RLm connected to the rows of the pixels PX may include two or more lines. The two or more lines may respectively transfer, for example, various signals including a signal for selecting (activating) photo detectors of a pixel, a signal for resetting a floating diffusion node, a signal for selecting a column line, a signal for adjusting a conversion gain, etc.

The ramp signal generator 130 may generate a ramp signal RS. The ramp signal generator 130 may operate under control of the timing generator 170. For example, the ramp signal generator 130 may operate in response to a control signal such as a ramp enable signal or a mode signal. In response to the ramp enable signal being activated, the ramp signal generator 130 may generate the ramp signal RS having a slope set based on the mode signal. For example, the ramp signal generator 130 may generate the ramp signal RS that continuously decreases or increases from an initial level over time.

The analog-to-digital conversion circuit 140 may be connected to columns of the pixels PX of the pixel array 110 through first to n-th column lines CL1 to CLn (n being a positive integer). The analog-to-digital conversion circuit 140 may include first to n-th analog-to-digital converters AD1 to ADn respectively connected to the first to n-th column lines CL1 to CLn. The first to n-th analog-to-digital converters AD1 to ADn may receive the ramp signal RS from the ramp signal generator 130 in common.

The first to n-th analog-to-digital converters AD1 to ADn may compare voltages (or currents) of the first to n-th column lines CL1 to CLn with the ramp signal RS. When the ramp signal RS continuously decreasing (or increasing) becomes smaller (or greater) than voltages (or currents) of the first to n-th column lines CL1 to CLn, the first to n-th analog-to-digital converters AD1 to ADn may perform count operations. The first to n-th analog-to-digital converters AD1 to ADn may convert and output count values into digital values. That is, the first to n-th analog-to-digital converters AD1 to ADn may output digital values corresponding to magnitudes (or amounts) of the voltages (or currents) output from the pixels PX to the first to n-th column lines CL1 to CLn.

Each of the first to n-th analog-to-digital converters AD1 to ADn may include at least two sub-converters. The sub-converters may be connected in common with the corresponding column line and may receive the ramp signal RS in common. Resolutions of the sub-converters may be about equal or different. The sub-converters may be activated at different timings to convert a voltage (or current) of the corresponding column line into digital values (or digital signals).

The memory circuit 150 may include first to n-th memories M1 to Mn respectively corresponding to the first to n-th analog-to-digital converters AD1 to ADn. The first to n-th memories M1 to Mn may store digital values (or digital signals) received from the first to n-th analog-to-digital converters AD1 to ADn and may transfer the stored values (or signals) to the logic circuit 160. For example, the first to n-th memories M1 to Mn may be implemented with latches or memory cells.

The logic circuit 160 may receive digital values (or digital signals) from the memory circuit 150. The logic circuit 160 may perform auto focusing based on the digital values (or the digital signals). For example, the logic circuit 160 may perform phase detection (PD) auto focusing. The logic circuit 160 may output digital values (or digital signals) corrected by the auto focusing as image data ID. Alternatively, the logic circuit 160 may output a digital HCG auto focus signal and a second digital HCG auto focus signal as information for auto focusing.

Under control of the logic circuit 160, the timing generator 170 may control timings when the camera module 100 operates. The timing generator 170 may control timings when the row driver 120 sequentially selects the first to m-th row lines RL1 to RLm and may control timings when signals are transferred through two or more lines included in a row line selected from the first to m-th row lines RL1 to RLm.

The timing generator 170 may control timings when the ramp signal generator 130 generates the ramp signal RS and initializes the ramp signal RS. The timing generator 170 may control timings when the first to n-th analog-to-digital converters AD1 to ADn start a count operation and a comparison operation and timings when the first to n-th analog-to-digital converters AD1 to ADn are initialized.

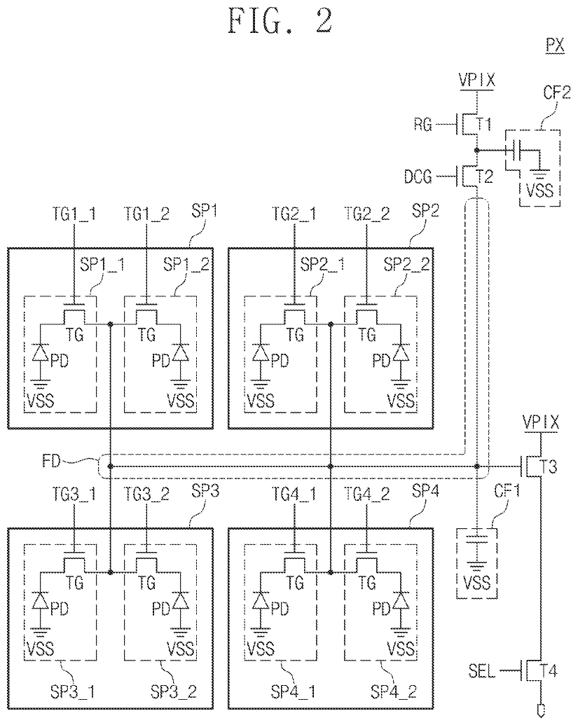

FIG. 2 illustrates an example of a pixel PX according to an embodiment of the present disclosure. Referring to FIGS. 1 and 2, the pixel PX may include a first sub-pixel SP1, a second sub-pixel SP2, a third sub-pixel SP3, and a fourth sub-pixel SP4.

The first to fourth sub-pixels SP1 to SP4 may be arranged in rows and columns in the pixel PX. The first sub-pixel SP1 and the second sub-pixel SP2 may be located in the same row. The third sub-pixel SP3 and the fourth sub-pixel SP4 may be located in the same row. The first sub-pixel SP1 and the third sub-pixel SP3 may be located in the same column. The second sub-pixel SP2 and the fourth sub-pixel SP4 may be located in the same column.

The first to fourth sub-pixels SP1 to SP4 may be connected in common with a floating diffusion node FD. Each of the first to fourth sub-pixels SP1 to SP4 may include a first region and a second region.

For example, the first sub-pixel SP1 may include a first region SP1_1 and a second region SP1_2. The first region SP1_1 of the first sub-pixel SP1 may include a photo detector PD, and a transfer gate TG selectively activating the photo detector PD (e.g., connected to the floating diffusion node FD to transfer a signal). The transfer gate TG may be turned on or turned off in response to a signal of a transfer line TG1_1. The second region SP1_2 of the first sub-pixel SP1 may include a photo detector PD, and a transfer gate TG selectively activating the photo detector PD (e.g., connected to the floating diffusion node FD to transfer a signal). The transfer gate TG may be turned on or turned off in response to a signal of a transfer line TG1_2.

The second sub-pixel SP2 may include a first region SP2_1 and a second region SP2_2. The first region SP2_1 of the second sub-pixel SP2 may include a photo detector PD, and a transfer gate TG selectively activating the photo detector PD (e.g., connected to the floating diffusion node FD to transfer a signal). The transfer gate TG may be turned on or turned off in response to a signal of a transfer line TG2_1. The second region SP2_2 of the second sub-pixel SP2 may include a photo detector PD, and a transfer gate TG selectively activating the photo detector PD (e.g., connected to the floating diffusion node FD to transfer a signal). The transfer gate TG may be turned on or turned off in response to a signal of a transfer line TG2_2.

The third sub-pixel SP3 may include a first region SP3_1 and a second region SP3_2. The first region SP3_1 of the third sub-pixel SP3 may include a photo detector PD, and a transfer gate TG selectively activating the photo detector PD (e.g., connected to the floating diffusion node FD to transfer a signal). The transfer gate TG may be turned on or turned off in response to a signal of a transfer line TG3_1. The second region SP3_2 of the third sub-pixel SP3 may include a photo detector PD, and a transfer gate TG selectively activating the photo detector PD (e.g., connected to the floating diffusion node FD to transfer a signal). The transfer gate TG may be turned on or turned off in response to a signal of a transfer line TG3_2.

The fourth sub-pixel SP4 may include a first region SP4_1 and a second region SP4_2. The first region SP4_1 of the fourth sub-pixel SP4 may include a photo detector PD, and a transfer gate TG selectively activating the photo detector PD (e.g., connected to the floating diffusion node FD to transfer a signal). The transfer gate TG may be turned on or turned off in response to a signal of a transfer line TG4_1. The second region SP4_2 of the fourth sub-pixel SP4 may include a photo detector PD, and a transfer gate TG selectively activating the photo detector PD (e.g., connected to the floating diffusion node FD to transfer a signal). The transfer gate TG may be turned on or turned off in response to a signal of a transfer line TG4_2.

That is, the pixel PX may include a plurality of sub-pixels (e.g., SP1 to SP4). Each of the plurality of sub-pixels (e.g., SP1 to SP4) may include a plurality of photo detectors PD. The photo detectors PD of the pixel PX may be electrically connected to the floating diffusion node FD independently of each other or may be electrically disconnected from the floating diffusion node FD independently of each other.

In an embodiment, the photo detectors PD of the first sub-pixel SP1 may correspond to a color filter of the same color. The photo detectors PD of the second sub-pixel SP2 may correspond to a color filter of the same color. The photo detectors PD of the third sub-pixel SP3 may correspond to a color filter of the same color. The photo detectors PD of the fourth sub-pixel SP4 may correspond to a color filter of the same color.

One of the first to fourth sub-pixels SP1 to SP4 may correspond to a blue color filter, another thereof may correspond to a red color filter, and the others thereof may correspond to a green color filter. The pixel PX and the color filters described with reference to FIG. 2 may be called a “tetra cell”.

The transfer lines TG1_1 and TG1_2 of the first sub-pixel SP1, the transfer lines TG2_1 and TG2_2 of the second sub-pixel SP2, the transfer lines TG3_1 and TG3_2 of the third sub-pixel SP3, and the transfer lines TG4_1 and TG4_2 of the fourth sub-pixel SP4 may be connected to a corresponding row line (e.g., RL) among the first to m-th row lines RL1 to RLm. For example, the corresponding row line RL may include two or more lines. Each of the two or more lines may be connected to at least one of the transfer lines TG1_1, TG1_2, TG2_1, TG2_2, TG3_1, TG3_2, TG4_1, and TG4_2 of the pixel PX.

The pixel PX may further include a first transistor T1 and a second transistor T2 that are connected in series between a power node to which a pixel voltage VPIX (e.g., a power supply voltage to be applied to the pixel PX) is applied and the floating diffusion node FD.

The first transistor T1 may include a gate to which a reset signal RG is transferred, a first end connected to the power node to which the pixel voltage VPIX is applied, and a second end connected to the second transistor T2. The first transistor T1 may be used to reset (or initialize) an internal voltage (or current) of the pixel PX. In the reset (or initialization) of the pixel PX, the first transistor T1, the second transistor T2, and the transfer gates TG of the pixel PX may be turned on. A voltage of the floating diffusion node FD and voltages of the photo detectors PD may be reset (or initialized) to the pixel voltage VPIX.

The second transistor T2 may include a gate to which a dynamic conversion gain signal DCG is applied, a first end connected to the first transistor T1, and a second end connected to the floating diffusion node FD. The second transistor T2 may adjust a gain when voltages (or currents) generated by the photo detectors PD are transferred to the floating diffusion node FD. For example, when the second transistor T2 is turned on, the floating diffusion node FD may be expanded to a region facing the first transistor T1, and thus, a capacitance of the floating diffusion node FD may increase. When the second transistor T2 is turned off, the floating diffusion node FD may be reduced to a region facing the second transistor T2, and thus, a capacitance of the floating diffusion node FD may decrease.

When the capacitance of the floating diffusion node FD increases, a gain may decrease when voltages (or currents) generated by the photo detectors PD are transferred to the floating diffusion node FD. When the capacitance of the floating diffusion node FD decreases, a gain may increase when voltages (or currents) generated by the photo detectors PD are transferred to the floating diffusion node FD. The second transistor T2 may dynamically adjust a range of the intensity of light sensed by the photo detectors PD by adjusting the capacitance of the floating diffusion node FD. That is, a high dynamic range (HDR) may be implemented.

In an embodiment, to improve the HDR, a first capacitor CF1 may be additionally connected to the floating diffusion node FD. Alternatively, in an embodiment, to improve the HDR, a second capacitor CF2 may be additionally connected between the second transistor T2 and the first transistor T1. In an embodiment, both the first capacitor CF1 and the second capacitor CF2 may be utilized.

The pixel PX may further include a third transistor T3 and a fourth transistor T4. The third transistor T3 may include a gate connected to the floating diffusion node FD, a first end connected to the power node to which the pixel voltage VPIX is applied, and a second end connected to the fourth transistor T4. The third transistor T3 may function as a source follower amplifier that amplifies a voltage of the floating diffusion node FD so as to be transferred to the fourth transistor T4.

The fourth transistor T4 may include a gate to which a selection signal SEL is transferred, a first end connected to the third transistor T3, and a second end connected to a corresponding column line CL among the first to n-th column lines CL1 to CLn. The fourth transistor T4 may transfer an output signal of the third transistor T3, for example, a voltage or a current to the corresponding column line CL.

In an embodiment, the reset signal RG, the dynamic conversion gain signal DCG, and the selection signal SEL may be transferred through different lines among the lines of the corresponding row line.

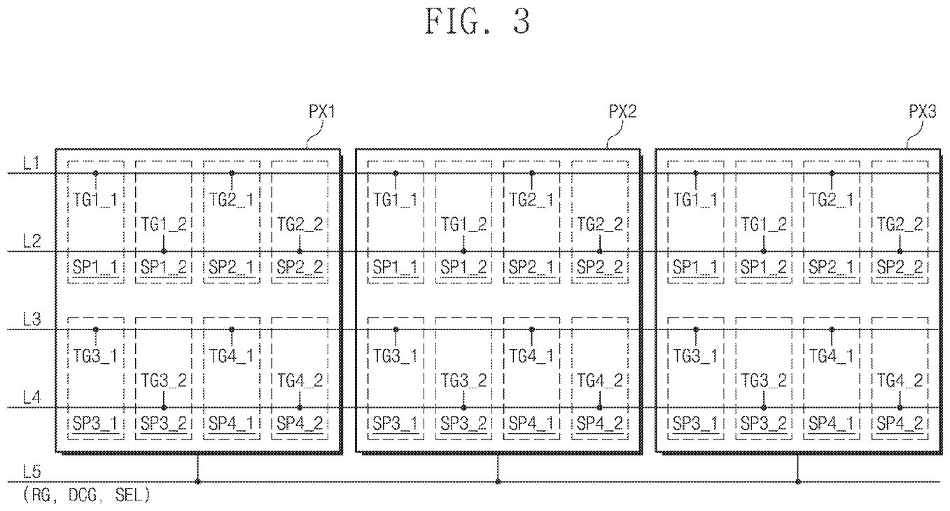

FIG. 3 illustrates a first example in which first to third pixels PX1 to PX3 belonging to the same row are connected to lines of a corresponding row line. For ease of illustration, the first to fourth sub-pixels SP1 to SP4 are not distinguished from each other, and the first regions SP1_1, SP2_1, SP3_1, and SP4_1 and the second regions SP1_2, SP2_2, SP3_2, and SP4_2 of the first to fourth sub-pixels SP1 to SP4 are only illustrated in FIG. 3.

Also, for ease of illustration, only the transfer lines TG1_1, TG2_1, TG3_1, and TG4_1 among components of the first regions SP1_1, SP2_1, SP3_1, and SP4_1 are illustrated, and only the transfer lines TG1_2, TG2_2, TG3_2, and TG4_2 among components of the second regions SP1_2, SP2_2, SP3_2, and SP4_2 are illustrated.

Referring to FIGS. 1, 2, and 3, one row line may include first to fifth lines L1 to L5. The first line L1 may be connected to the transfer lines TG1_1 of the first regions SP1_1 of the first sub-pixels SP1 of the first to third pixels PX1 to PX3 and may be connected to the transfer lines TG2_1 of the second regions SP2_1 of the second sub-pixels SP2 of the first to third pixels PX1 to PX3. The first line L1 may activate the first regions SP1_1 and SP2_1 of the first and second sub-pixels SP1 and SP2, for example, the photo detectors PD of the left side.

The second line L2 may be connected to the transfer lines TG1_2 of the second regions SP1_2 of the first sub-pixels SP1 of the first to third pixels PX1 to PX3 and may be connected to the transfer lines TG2_2 of the second regions SP2_2 of the second sub-pixels SP2 of the first to third pixels PX1 to PX3. The second line L2 may activate the second regions SP1_2 and SP2_2 of the first and second sub-pixels SP1 and SP2, for example, the photo detectors PD of the right side.

The third line L3 may be connected to the transfer lines TG3_1 of the first regions SP3_1 of the third sub-pixels SP3 of the first to third pixels PX1 to PX3 and may be connected to the transfer lines TG4_1 of the first regions SP4_1 of the fourth sub-pixels SP4 of the first to third pixels PX1 to PX3. The third line L3 may activate the first regions SP3_1 and SP4_1 of the third and fourth sub-pixels SP3 and SP4, for example, the photo detectors PD of the left side.

The fourth line L4 may be connected to the transfer lines TG3_2 of the second regions SP3_2 of the third sub-pixels SP3 of the first to third pixels PX1 to PX3 and may be connected to the transfer lines TG4_2 of the second regions SP4_2 of the fourth sub-pixels SP4 of the first to third pixels PX1 to PX3. The fourth line L4 may activate the second regions SP3_2 and SP4_2 of the third and fourth sub-pixels SP3 and SP4, for example, the photo detectors PD of the right side.

The fifth lines L5 may be connected in common with the first to third pixels PX1 to PX3. The fifth lines L5 may include a line that transfers the reset signal RG, a line that transfers the dynamic conversion gain signal DCG, and a line that transfers the selection signal SEL.

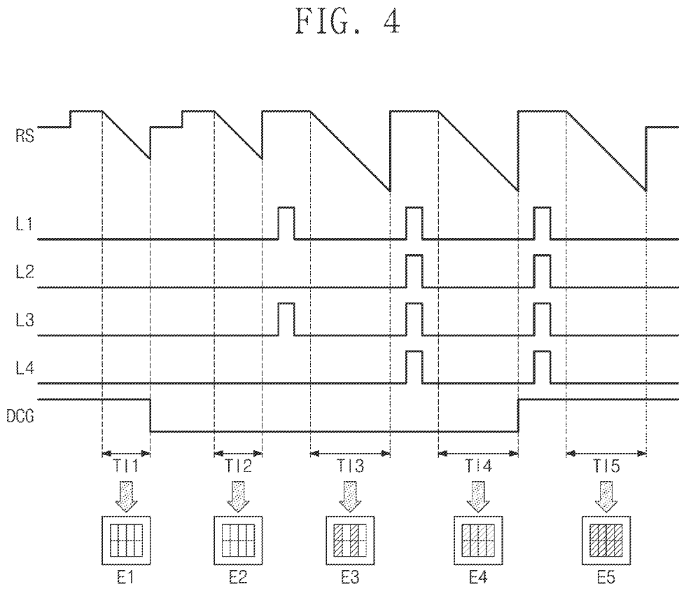

FIG. 4 illustrates an example in which the camera module 100 captures the image data ID of the pixels PX1 to PX3 in one row based on a wire structure of FIG. 3. In an embodiment, reset and exposure operations may be performed prior to the example illustrated in FIG. 4. The reset operation may include resetting (or initializing) the photo detectors PD and the floating diffusion nodes FD of one row of pixels PX selected from rows of pixels PX to the pixel voltage VPIX. The exposure operation may include a time interval which corresponds to a given time interval after the reset operation and in which the photo detectors PD generate signals in response to an incident light.

Referring to FIGS. 1, 2, 3, and 4, the process in which one row captures the image data ID of the pixels PX1 to PX3 may be performed by first to fifth time intervals TI1 to TI5.

The first time interval TI1 may correspond to a reset interval of a low conversion gain (LCG). In an embodiment, signals of the first to fourth lines L1 to L4 may be maintained at an inactive state (e.g., a low level), and the photo detectors PD of the pixels PX1 to PX3 do not output signals to the floating diffusion node FD. The dynamic conversion gain signal DCG may maintain an active state (e.g., a high level).

A first sub-converter among sub-converters connected to each column line CL may convert a signal of each column line CL, which exists when there are no outputs of the photo detectors PD, for example, an LCG noise signal into a digital value (or a digital signal) based on the ramp signal RS. Referring to a first example E1 of FIG. 4, output signals of the 8 photo detectors PD of each pixel PX are not captured, and thus, 8 boxes corresponding to the 8 photo detectors PD of each pixel PX are depicted as empty.

The second time interval TI2 may correspond to a reset interval of a high conversion gain (HCG). In an embodiment, signals of the first to fourth lines L1 to L4 may be maintained at the inactive state (e.g., the low level), and the photo detectors PD of the pixels PX1 to PX3 do not output signals to the floating diffusion node FD. The dynamic conversion gain signal DCG may maintain an inactive state (e.g., the low level).

A second sub-converter among the sub-converters connected to each column line CL may convert a signal of each column line CL, which exists when there are no outputs of the photo detectors PD, for example, an HCG noise signal into a digital value (or a digital signal) based on the ramp signal RS. Referring to a second example E2 of FIG. 4, output signals of the 8 photo detectors PD of each pixel PX are not captured, and thus, 8 boxes corresponding to the 8 photo detectors PD of each pixel PX are depicted as empty.

The third time interval TI3 may correspond to a first signal capture interval of the HCG. During the third time interval TI3, the camera module 100 may capture a signal necessary for auto focusing. Signals of the first and third lines L1 and L3 may transition from the inactive state (e.g., the low level) to the active state (e.g., the high level) and may then transition from the active state to the inactive state. Signals of the second and fourth lines L2 and L4 may maintain the inactive state. The dynamic conversion gain signal DCG may maintain the inactive state (e.g., the low level). Outputs of the photo detectors PD of the first regions SP1_1, SP2_1, SP3_1, and SP4_1 of the first to fourth sub-pixels SP1 to SP4 of each pixel PX may be binned at the floating diffusion node FD.

The second sub-converter among the sub-converters connected to each column line CL may convert a signal of each column line CL, which corresponds to the outputs of the photo detectors PD of the first regions SP1_1, SP2_1, SP3_1, and SP4_1 of the first to fourth sub-pixels SP1 to SP4, for example, an HCG auto focus signal into a digital value (or a digital signal) (e.g., a digital HCG auto focus signal) based on the ramp signal RS. Referring to a third example E3 of FIG. 4, output signals of the photo detectors PD of a first region of each sub-pixel are captured, and thus, 4 boxes corresponding to the photo detectors PD of a first region of each sub-pixel are depicted as filled by slashes, and the remaining boxes are depicted as empty.

In an embodiment, the second sub-converters connected to each column line CL may remove a noise component from the digital HCG auto focus signal by subtracting half of the digital HCG noise signal from the digital HCG auto focus signal.

The fourth time interval TI4 may correspond to a second signal capture interval of the HCG. During the fourth time interval TI4, the camera module 100 may capture an image signal of a high conversion gain (HCG). Signals of the first to fourth lines L1 to L4 may transition from the inactive state (e.g., the low level) to the active state (e.g., the high level) and may then transition from the active state to the inactive state. The dynamic conversion gain signal DCG may maintain the inactive state (e.g., the low level). Outputs of the photo detectors PD of each pixel PX may be binned at the floating diffusion node FD.

The second sub-converter among the sub-converters connected to each column line CL may convert a signal of each column line CL, which corresponds to the outputs of the photo detectors PD of the first to fourth sub-pixels SP1 to SP4, for example, an HCG sum signal into a digital value (or a digital signal) (e.g., a digital HCG sum signal) based on the ramp signal RS. Referring to a fourth example E4 of FIG. 4, output signals of the photo detectors PD of each pixel PX are captured, and thus, 8 boxes corresponding to the photo detectors PD of each pixel PX are depicted as filled by slashes.

In an embodiment, the second sub-converters connected to each column line CL may remove a noise component from the digital HCG sum signal by subtracting the digital HCG noise signal from the digital HCG sum signal.

In an embodiment, the logic circuit 160 may generate a second digital HCG auto focus signal by subtracting the digital HCG auto focus signal from the digital HCG sum signal. The logic circuit 160 may perform phase detection auto focusing based on the digital HCG auto focus signal and the second digital HCG auto focus signal. Alternatively, the logic circuit 160 may output the digital HCG auto focus signal and the second digital HCG auto focus signal as information for auto focusing.

The fifth time interval TI5 may correspond to a signal capture interval of the LCG. During the fifth time interval TI5, the camera module 100 may capture an image signal of a low conversion gain (LCG). Signals of the first to fourth lines L1 to L4 may transition from the inactive state (e.g., the low level) to the active state (e.g., the high level) and may then transition from the active state to the inactive state. The dynamic conversion gain signal DCG may maintain the active state (e.g., the high level). Outputs of the photo detectors PD of each pixel PX may be binned at the floating diffusion node FD.

The first sub-converter among the sub-converters connected to each column line CL may convert a signal of each column line CL, which corresponds to the outputs of the photo detectors PD of the first to fourth sub-pixels SP1 to SP4, for example, an LCG sum signal into a digital value (or a digital signal) (e.g., a digital LCG sum signal) based on the ramp signal RS. Referring to a fifth example E5 of FIG. 4, output signals of the photo detectors PD of each pixel PX are captured, and thus, 8 boxes corresponding to the photo detectors PD of each pixel PX are depicted as filled by slashes.

In an embodiment, the first sub-converters connected to each column line CL may remove a noise component from the digital LCG sum signal by subtracting the digital LCG noise signal from the digital LCG sum signal.

As described with reference to FIG. 4, the camera module 100 may perform auto focusing by using all the photo detectors PD belonging to each pixel PX. However, when the intensity of a signal transferred from the first region of each sub-pixel to the floating diffusion node FD in the third time interval TI3 is greater than a capacity (e.g., a capacitance) of the floating diffusion node FD, the digital HCG auto focus signal may be saturated. When the digital HCG auto focus signal is saturated, the camera module 100 may fail in auto focusing.

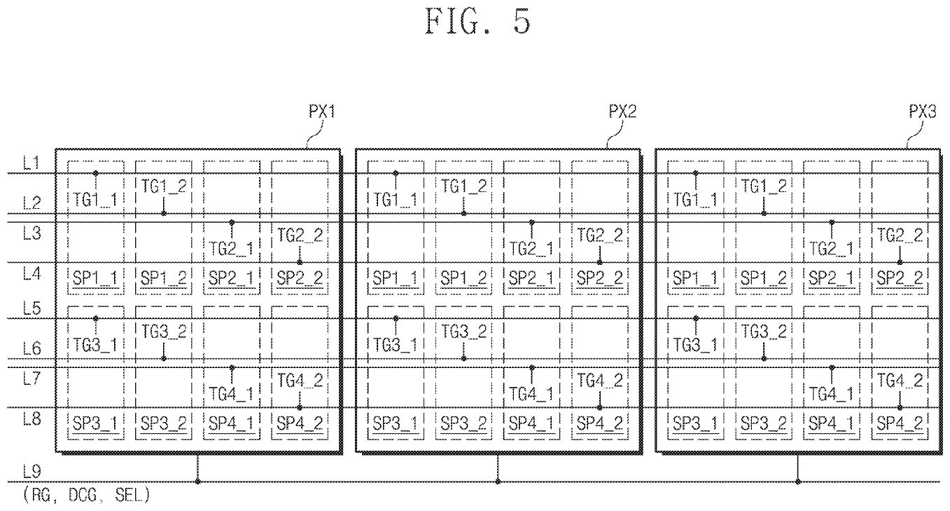

FIG. 5 illustrates a second example in which the first to third pixels PX1 to PX3 belonging to the same row are connected to lines of a corresponding row line. As in the first example E1 illustrated in FIG. 3, for ease of illustration, some components of the first to third pixels PX1 to PX3 are omitted.

Referring to FIGS. 1, 2, and 5, one row line may include first to ninth lines L1 to L9. The first line L1 may be connected to the transfer lines TG1_1 of the first regions SP1_1 of the first sub-pixels SP1 of the first to third pixels PX1 to PX3. The first line L1 may activate the first regions SP1_1 of the first sub-pixels SP1, for example, the photo detectors PD of the left side.

The second line L2 may be connected to the transfer lines TG1_2 of the second regions SP1_2 of the first sub-pixels SP1 of the first to third pixels PX1 to PX3. The second line L2 may activate the second regions SP1_2 of the first sub-pixels SP1, for example, the photo detectors PD of the right side.

The third line L3 may be connected to the transfer lines TG2_1 of the first regions SP2_1 of the second sub-pixels SP2 of the first to third pixels PX1 to PX3. The third line L3 may activate the first regions SP2_1 of the second sub-pixels SP2, for example, the photo detectors PD of the left side.

The fourth line L4 may be connected to the transfer lines TG2_2 of the second regions SP2_2 of the second sub-pixels SP2 of the first to third pixels PX1 to PX3. The fourth line L4 may activate the second regions SP2_2 of the second sub-pixels SP2, for example, the photo detectors PD of the right side.

The fifth line L5 may be connected to the transfer lines TG3_1 of the first regions SP3_1 of the third sub-pixels SP3 of the first to third pixels PX1 to PX3. The fifth line L5 may activate the first regions SP3_1 of the third sub-pixels SP3, for example, the photo detectors PD of the left side.

The sixth line L6 may be connected to the transfer lines TG3_2 of the second regions SP3_2 of the third sub-pixels SP3 of the first to third pixels PX1 to PX3. The sixth line L6 may activate the second regions SP3_2 of the third sub-pixels SP3, for example, the photo detectors PD of the right side.

The seventh line L7 may be connected to the transfer lines TG4_1 of the first regions SP4_1 of the fourth sub-pixels SP4 of the first to third pixels PX1 to PX3. The seventh line L7 may activate the first regions SP4_1 of the fourth sub-pixels SP4, for example, the photo detectors PD of the left side.

The eighth line L8 may be connected to the transfer lines TG4_2 of the second regions SP4_2 of the fourth sub-pixels SP4 of the first to third pixels PX1 to PX3. The eighth line L8 may activate the second regions SP4_2 of the fourth sub-pixels SP4, for example, the photo detectors PD of the right side.

The ninth lines L9 may be connected in common with the first to third pixels PX1 to PX3. The ninth lines L9 may include a line that transfers the reset signal RG, a line that transfers the dynamic conversion gain signal DCG, and a line that transfers the selection signal SEL.

Compared to the example of FIG. 3, in the example of FIG. 5, photo detectors of each pixel may be activated or deactivated by independent transfer lines. Accordingly, the camera module 100 implemented according to the example of FIG. 5 may capture a digital HCG auto focus signal in various manners.

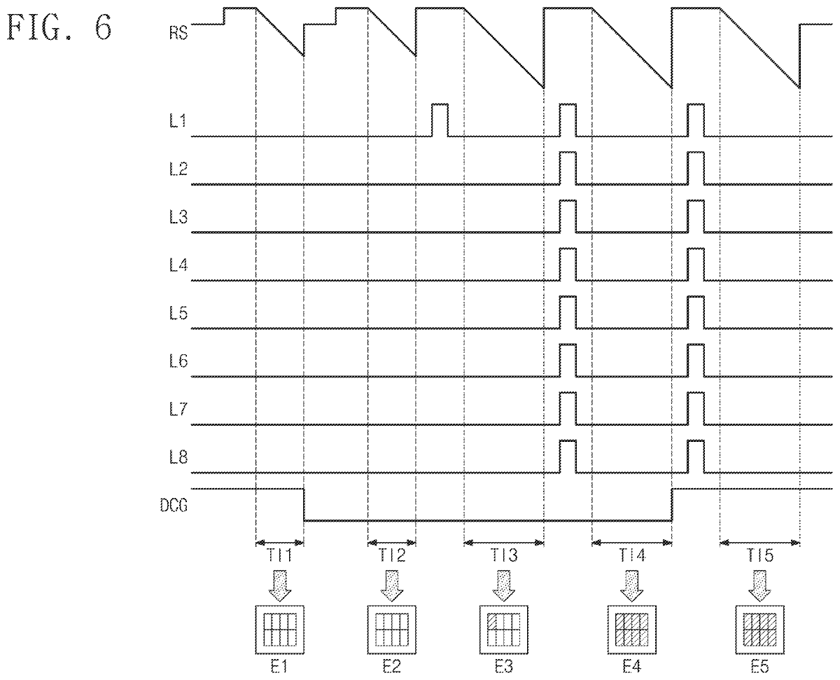

FIG. 6 illustrates an example in which the camera module 100 captures the image data ID of the pixels PX1 to PX3 in one row based on a wire structure of FIG. 5. Referring to FIGS. 1, 2, 5, and 6, the camera module 100 may capture the image data ID of the pixels PX1 to PX3 in one row based on first to fifth time intervals TI1 to TI5.

In an embodiment, as described with reference to FIG. 4, the reset operation and the exposure operation may be performed prior to the first to fifth time intervals TI1 to TI5 of FIG. 6. Operations in the first time interval TI1, the second time interval TI2, the fourth time interval TI4, and the fifth time interval TI5 may be identical to the operations described with reference to FIG. 4. Thus, a further description thereof will be omitted to avoid redundancy.

In the third time interval TI3, a signal of the first line L1 may transition from the inactive state (e.g., the low level) to the active state (e.g., the high level) and may then transition from the active state to the inactive state. Signals of the second to eighth lines L2 and L8 may maintain the inactive state. The dynamic conversion gain signal DCG may maintain the inactive state (e.g., the low level).

The second sub-converter among the sub-converters connected to each column line CL may convert a signal of each column line CL, which corresponds to the outputs of the photo detector PD of the first region SP1_1 of the first sub-pixel SP1, for example, an HCG auto focus signal into a digital value (or a digital signal) (e.g., a digital HCG auto focus signal) based on the ramp signal RS. Referring to a third example E3 of FIG. 6, an output signal of the photo detector PD of the first region SP1_1 of the first sub-pixel SP1 is captured, and thus, one box corresponding to the photo detector PD of the first region SP1_1 of the first sub-pixel SP1 is depicted as filled by slashes, and the remaining boxes are depicted as empty.

In an embodiment, the second sub-converters connected to each column line CL may remove a noise component from the digital HCG auto focus signal by subtracting half of the digital HCG noise signal from the digital HCG auto focus signal.

Compared to the third example E3 of FIG. 4, in the example E3 of FIG. 6, the digital HCG auto focus signal is generated from one photo detector PD among 8 photo detectors PD. Accordingly, the digital HCG auto focus signal may be prevented from being saturated.

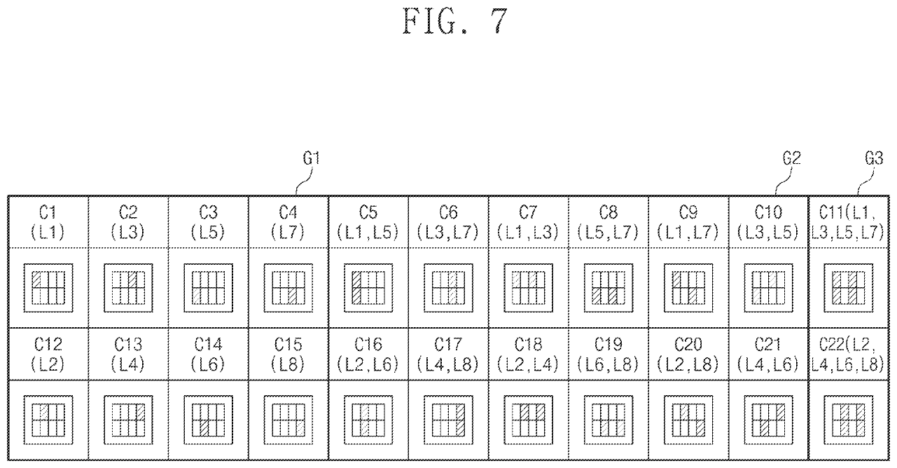

FIG. 7 illustrates various cases of the third example E3 in which the digital HCG auto focus signal is generated based on the wire structure of FIG. 5. Referring to FIGS. 1, 2, 5, 6, and 7, in 1st to 11th cases C1 to C11, the camera module 100 may generate the digital HCG auto focus signal by using a photo detector(s) PD of a first region of at least one sub-pixel in each pixel PX.

In the 1st to 4th cases C1 to C4, the camera module 100 may generate the digital HCG auto focus signal by using one photo detector of the photo detectors PD of each pixel PX.

In the 1st case C1, the camera module 100 may generate the digital HCG auto focus signal from an output signal of the photo detector PD of the first region SP1_1 (e.g., a left side of a left sub-pixel in an upper row) of the first sub-pixel SP1 in each pixel PX. In the third time interval TI3, a signal of the first line L1 may transition from the inactive state (e.g., the low level) to the active state (e.g., the high level) and may then transition from the active state to the inactive state.

In the 2nd case C2, the camera module 100 may generate the digital HCG auto focus signal from an output signal of the photo detector PD of the first region SP2_1 (e.g., a left side of a right sub-pixel in an upper row) of the second sub-pixel SP2 in each pixel PX. In the third time interval TI3, a signal of the third line L3 may transition from the inactive state (e.g., the low level) to the active state (e.g., the high level) and may then transition from the active state to the inactive state.

In the 3rd case C3, the camera module 100 may generate the digital HCG auto focus signal from an output signal of the photo detector PD of the first region SP3_1 (e.g., a left side of a left sub-pixel in a lower row) of the third sub-pixel SP3 in each pixel PX. In the third time interval TI3, a signal of the fifth line L5 may transition from the inactive state (e.g., the low level) to the active state (e.g., the high level) and may then transition from the active state to the inactive state.

In the 4th case C4, the camera module 100 may generate the digital HCG auto focus signal from an output signal of the photo detector PD of the first region SP4_1 (e.g., a left side of a right sub-pixel in the lower row) of the fourth sub-pixel SP4 in each pixel PX. In the third time interval TI3, a signal of the seventh line L7 may transition from the inactive state (e.g., the low level) to the active state (e.g., the high level) and may then transition from the active state to the inactive state.

In the 5th to 10th cases C5 to C10, the camera module 100 may generate the digital HCG auto focus signal by using two photo detectors of the photo detectors PD of each pixel PX.

In the 5th case C5, the camera module 100 may generate the digital HCG auto focus signal from an output signal of the photo detector PD of the first region SP1_1 (e.g., a left side of the left sub-pixel in the upper row) of the first sub-pixel SP1 in each pixel PX and an output signal of the photo detector PD of the first region SP3_1 (e.g., a left side of the left sub-pixel in the lower row) of the third sub-pixel SP3 in each pixel PX. In the third time interval TI3, signals of the first and fifth lines L1 and L5 may transition from the inactive state (e.g., the low level) to the active state (e.g., the high level) and may then transition from the active state to the inactive state.

In the 6th case C6, the camera module 100 may generate the digital HCG auto focus signal from an output signal of the photo detector PD of the first region SP2_1 (e.g., a left side of the right sub-pixel in the upper row) of the second sub-pixel SP2 in each pixel PX and an output signal of the photo detector PD of the first region SP4_1 (e.g., a left side of the right sub-pixel in the lower row) of the fourth sub-pixel SP4 in each pixel PX. In the third time interval TI3, signals of the third and seventh lines L3 and L7 may transition from the inactive state (e.g., the low level) to the active state (e.g., the high level) and may then transition from the active state to the inactive state.

In the 7th case C7, the camera module 100 may generate the digital HCG auto focus signal from an output signal of the photo detector PD of the first region SP1_1 (e.g., a left side of the left sub-pixel in the upper row) of the first sub-pixel SP1 in each pixel PX and an output signal of the photo detector PD of the first region SP2_1 (e.g., a left side of the right sub-pixel in the upper row) of the second sub-pixel SP2 in each pixel PX. In the third time interval TI3, signals of the first and third lines L1 and L3 may transition from the inactive state (e.g., the low level) to the active state (e.g., the high level) and may then transition from the active state to the inactive state.

In the 8th case C8, the camera module 100 may generate the digital HCG auto focus signal from an output signal of the photo detector PD of the first region SP3_1 (e.g., a left side of the left sub-pixel in the lower row) of the third sub-pixel SP3 in each pixel PX and an output signal of the photo detector PD of the first region SP4_1 (e.g., a left side of the right sub-pixel in the lower row) of the fourth sub-pixel SP4 in each pixel PX. In the third time interval TI3, signals of the fifth and seventh lines L5 and L7 may transition from the inactive state (e.g., the low level) to the active state (e.g., the high level) and may then transition from the active state to the inactive state.

In the 9th case C9, the camera module 100 may generate the digital HCG auto focus signal from an output signal of the photo detector PD of the first region SP1_1 (e.g., a left side of the left sub-pixel in the upper row) of the first sub-pixel SP1 in each pixel PX and an output signal of the photo detector PD of the first region SP4_1 (e.g., a left side of the right sub-pixel in the lower row) of the fourth sub-pixel SP4 in each pixel PX. In the third time interval TI3, signals of the first and seventh lines L1 and L7 may transition from the inactive state (e.g., the low level) to the active state (e.g., the high level) and may then transition from the active state to the inactive state.

In the 10th case C10, the camera module 100 may generate the digital HCG auto focus signal from an output signal of the photo detector PD of the first region SP2_1 (e.g., a left side of the right sub-pixel in the upper row) of the second sub-pixel SP2 in each pixel PX and an output signal of the photo detector PD of the first region SP3_1 (e.g., a left side of the left sub-pixel in the lower row) of the third sub-pixel SP3 in each pixel PX. In the third time interval TI3, signals of the third and fifth lines L3 and L5 may transition from the inactive state (e.g., the low level) to the active state (e.g., the high level) and may then transition from the active state to the inactive state.

In the 11th case C11, the camera module 100 may generate the digital HCG auto focus signal by using four photo detectors of the photo detectors PD of each pixel PX. The camera module 100 may generate the digital HCG auto focus signal from output signals of the photo detectors PD of the first regions SP1_1 to SP4_1 (e.g., a left side of all the sub-pixels) of the first to fourth sub-pixels SP1 to SP4. In the third time interval TI3, signals of the first, third, fifth, and seventh lines L1, L3, L5, and L7 may transition from the inactive state (e.g., the low level) to the active state (e.g., the high level) and may then transition from the active state to the inactive state.

In the 12th to 22nd cases C12 to C22, the camera module 100 may generate the digital HCG auto focus signal by using a photo detector(s) PD of a second region of at least one sub-pixel in each pixel PX.

In the 12th to 15th cases C12 to C15, the camera module 100 may generate the digital HCG auto focus signal by using one photo detector of the photo detectors PD of each pixel PX.

In the 12nd case C12, the camera module 100 may generate the digital HCG auto focus signal from an output signal of the photo detector PD of the second region SP1_2 (e.g., a right side of the left sub-pixel in the upper row) of the first sub-pixel SP1 in each pixel PX. In the third time interval T13, a signal of the second line L2 may transition from the inactive state (e.g., the low level) to the active state (e.g., the high level) and may then transition from the active state to the inactive state.

In the 13th case C13, the camera module 100 may generate the digital HCG auto focus signal from an output signal of the photo detector PD of the second region SP2_2 (e.g., a right side of the right sub-pixel in the upper row) of the second sub-pixel SP2 in each pixel PX. In the third time interval T13, a signal of the fourth line L4 may transition from the inactive state (e.g., the low level) to the active state (e.g., the high level) and may then transition from the active state to the inactive state.

In the 14th case C14, the camera module 100 may generate the digital HCG auto focus signal from an output signal of the photo detector PD of the second region SP3_2 (e.g., a right side of the left sub-pixel in the lower row) of the third sub-pixel SP3 in each pixel PX. In the third time interval T13, a signal of the sixth line L6 may transition from the inactive state (e.g., the low level) to the active state (e.g., the high level) and may then transition from the active state to the inactive state.

In the 15th case C15, the camera module 100 may generate the digital HCG auto focus signal from an output signal of the photo detector PD of the second region SP4_2 (e.g., a right side of the right sub-pixel in the lower row) of the fourth sub-pixel SP4 in each pixel PX. In the third time interval T13, a signal of the eighth line L8 may transition from the inactive state (e.g., the low level) to the active state (e.g., the high level) and may then transition from the active state to the inactive state.

In the 16th to 21st cases C16 to C21, the camera module 100 may generate the digital HCG auto focus signal by using two photo detectors of the photo detectors PD of each pixel PX.

In the 16th case C16, the camera module 100 may generate the digital HCG auto focus signal from an output signal of the photo detector PD of the second region SP1_2 (e.g., a right side of the left sub-pixel in the upper row) of the first sub-pixel SP1 in each pixel PX and an output signal of the photo detector PD of the second region SP3_2 (e.g., a right side of the left sub-pixel in the lower row) of the third sub-pixel SP3 in each pixel PX. In the third time interval TI3, signals of the second and sixth lines L2 and L6 may transition from the inactive state (e.g., the low level) to the active state (e.g., the high level) and may then transition from the active state to the inactive state.

In the 17th case C17, the camera module 100 may generate the digital HCG auto focus signal from an output signal of the photo detector PD of the second region SP2_2 (e.g., a right side of the right sub-pixel in the upper row) of the second sub-pixel SP2 in each pixel PX and an output signal of the photo detector PD of the second region SP4_2 (e.g., a right side of the right sub-pixel in the lower row) of the fourth sub-pixel SP4 in each pixel PX. In the third time interval TI3, signals of the fourth and eighth lines L4 and L8 may transition from the inactive state (e.g., the low level) to the active state (e.g., the high level) and may then transition from the active state to the inactive state.

In the 18th case C18, the camera module 100 may generate the digital HCG auto focus signal from an output signal of the photo detector PD of the second region SP1_2 (e.g., a right side of the left sub-pixel in the upper row) of the first sub-pixel SP1 in each pixel PX and an output signal of the photo detector PD of the second region SP2_2 (e.g., a right side of the right sub-pixel in the upper row) of the second sub-pixel SP2 in each pixel PX. In the third time interval TI3, signals of the second and fourth lines L2 and L4 may transition from the inactive state (e.g., the low level) to the active state (e.g., the high level) and may then transition from the active state to the inactive state.

In the 19th case C19, the camera module 100 may generate the digital HCG auto focus signal from an output signal of the photo detector PD of the second region SP3_2 (e.g., a right side of the left sub-pixel in the lower row) of the third sub-pixel SP3 in each pixel PX and an output signal of the photo detector PD of the second region SP4_2 (e.g., a right side of the right sub-pixel in the lower row) of the fourth sub-pixel SP4 in each pixel PX. In the third time interval TI3, signals of the sixth and eighth lines L6 and L8 may transition from the inactive state (e.g., the low level) to the active state (e.g., the high level) and may then transition from the active state to the inactive state.

In the 20th case C20, the camera module 100 may generate the digital HCG auto focus signal from an output signal of the photo detector PD of the second region SP1_2 (e.g., a right side of the left sub-pixel in the upper row) of the first sub-pixel SP1 in each pixel PX and an output signal of the photo detector PD of the second region SP4_2 (e.g., a right side of the right sub-pixel in the lower row) of the fourth sub-pixel SP4 in each pixel PX. In the third time interval TI3, signals of the second and eighth lines L2 and L8 may transition from the inactive state (e.g., the low level) to the active state (e.g., the high level) and may then transition from the active state to the inactive state.

In the 21st case C21, the camera module 100 may generate the digital HCG auto focus signal from an output signal of the photo detector PD of the second region SP2_2 (e.g., a right side of the right sub-pixel in the upper row) of the second sub-pixel SP2 in each pixel PX and an output signal of the photo detector PD of the second region SP3_2 (e.g., a right side of the left sub-pixel in the lower row) of the third sub-pixel SP3 in each pixel PX.

In the third time interval TI3, signals of the fourth and sixth lines L4 and L6 may transition from the inactive state (e.g., the low level) to the active state (e.g., the high level) and may then transition from the active state to the inactive state.

In the 22nd case C22, the camera module 100 may generate the digital HCG auto focus signal by using four photo detectors of the photo detectors PD of each pixel PX. The camera module 100 may generate the digital HCG auto focus signal from output signals of the photo detectors PD of the second regions SP1_2 to SP4_2 (e.g., a right side of all the sub-pixels) of the first to fourth sub-pixels SP1 to SP4. In the third time interval TI3, signals of the second, fourth, sixth, and eighth lines L2, L4, L6, and L8 may transition from the inactive state (e.g., the low level) to the active state (e.g., the high level) and may then transition from the active state to the inactive state.

In an embodiment, the camera module 100 may generate the digital HCG auto focus signal by using half or less of the photo detectors PD of the photo detectors PD of each pixel PX. For example, an analog-to-digital conversion circuit of the camera module 100 may generate a first signal in response to the row driver 120 activating signals of half or less of the photo detectors PD included in one pixel PX, and the auto focus signal may be generated based on the first signal.

The 1st to 4th cases C1 to C4 and the 12th to 15th cases C12 to C15 belonging to a first group G1 may generate the digital HCG auto focus signal by using one photo detector of the photo detectors PD belonging to each pixel PX.

The logic circuit 160 may generate the second digital HCG auto focus signal by subtracting four times the digital HCG auto focus signal from the digital HCG sum signal. Alternatively, the logic circuit 160 may generate the second digital HCG auto focus signal by subtracting the digital HCG auto focus signal from the digital LCG sum signal. The logic circuit 160 may perform phase detection auto focusing based on the digital HCG auto focus signal and the second digital HCG auto focus signal. Alternatively, the logic circuit 160 may output the digital HCG auto focus signal and the second digital HCG auto focus signal as information for auto focusing.

The 5th to 10th cases C5 to C10 and the 16th to 21st cases C16 to C21 belonging to a second group G2 may generate the digital HCG auto focus signal by using two photo detectors of the photo detectors PD belonging to each pixel PX.

The logic circuit 160 may generate the second digital HCG auto focus signal by subtracting two times the digital HCG auto focus signal from the digital HCG sum signal. Alternatively, the logic circuit 160 may generate the second digital HCG auto focus signal by subtracting half of the digital HCG auto focus signal from the digital LCG sum signal. The logic circuit 160 may perform phase detection auto focusing based on the digital HCG auto focus signal and the second digital HCG auto focus signal. Alternatively, the logic circuit 160 may output the digital HCG auto focus signal and the second digital HCG auto focus signal as information for auto focusing.

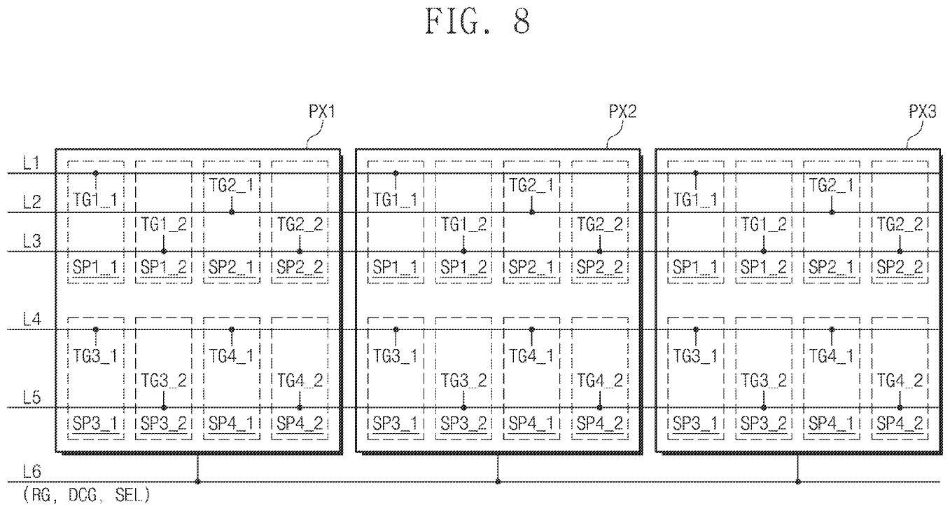

FIG. 8 illustrates a third example in which the first to third pixels PX1 to PX3 belonging to the same row are connected to lines of a corresponding row line. In an embodiment, the camera module 100 implemented in the wire structure of FIG. 8 may generate the HCG auto focus signal based on the 1st and 2nd cases C1 and C2 of FIG. 7. As in the first example E1 illustrated in FIG. 3, for ease of illustration, some components of the first to third pixels PX1 to PX3 are omitted.

Referring to FIGS. 1, 2, 7, and 8, one row line may include first to sixth lines L1 to L6. The first line L1 may be connected to the transfer lines TG1_1 of the first regions SP1_1 of the first sub-pixels SP1 of the first to third pixels PX1 to PX3. The first line L1 may activate the first regions SP1_1 of the first sub-pixels SP1, for example, the photo detectors PD of the left side.

The second line L2 may be connected to the transfer lines TG2_1 of the first regions SP2_1 of the second sub-pixels SP2 of the first to third pixels PX1 to PX3. The second line L2 may activate the first regions SP2_1 of the second sub-pixels SP2, for example, the photo detectors PD of the left side.

The third line L3 may be connected to the transfer lines TG1_2 of the second regions SP1_2 of the first sub-pixels SP1 of the first to third pixels PX1 to PX3 and may be connected to the transfer lines TG2_2 of the second regions SP2_2 of the second sub-pixels SP2 of the first to third pixels PX1 to PX3. The third line L3 may activate the second regions SP1_2 and SP2_2 of the first and second sub-pixels SP1 and SP2, for example, the photo detectors PD of the right side.

The fourth line L4 may be connected to the transfer lines TG3_1 of the first regions SP3_1 of the third sub-pixels SP3 of the first to third pixels PX1 to PX3 and may be connected to the transfer lines TG4_1 of the first regions SP4_1 of the fourth sub-pixels SP4 of the first to third pixels PX1 to PX3. The fourth line L4 may activate the first regions SP3_1 and SP4_1 of the third and fourth sub-pixels SP3 and SP4, for example, the photo detectors PD of the left side.

The fifth line L5 may be connected to the transfer lines TG3_2 of the second regions SP3_2 of the third sub-pixels SP3 of the first to third pixels PX1 to PX3 and may be connected to the transfer lines TG4_2 of the second regions SP4_2 of the fourth sub-pixels SP4 of the first to third pixels PX1 to PX3. The fifth line L5 may activate the second regions SP3_2 and SP4_2 of the third and fourth sub-pixels SP3 and SP4, for example, the photo detectors PD of the right side.

The sixth lines L6 may be connected in common with the first to third pixels PX1 to PX3. The sixth lines L6 may include a line that transfers the reset signal RG, a line that transfers the dynamic conversion gain signal DCG, and a line that transfers the selection signal SEL.

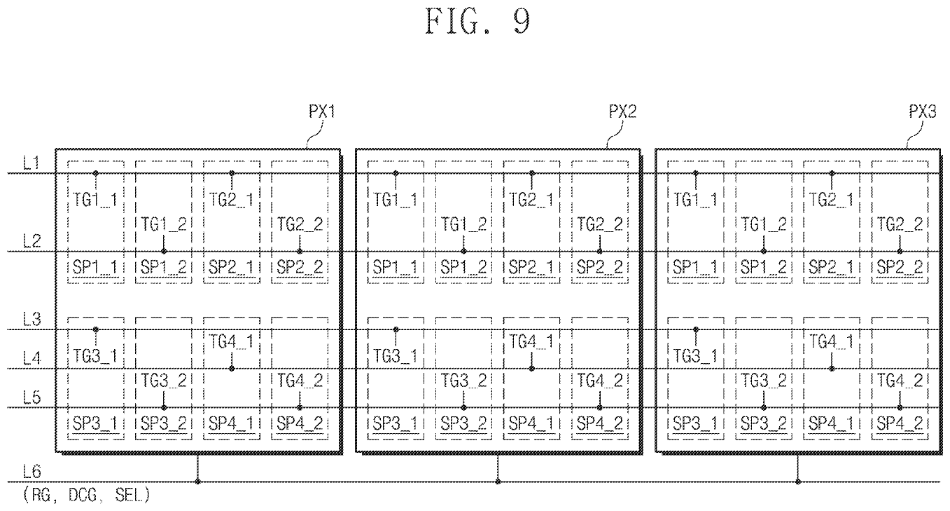

FIG. 9 illustrates a fourth example in which the first to third pixels PX1 to PX3 belonging to the same row are connected to lines of a corresponding row line. In an embodiment, the camera module 100 implemented in the wire structure of FIG. 9 may generate the HCG auto focus signal based on the 3rd and 4th cases C3 and C4 of FIG. 7. As in the first example E1 illustrated in FIG. 3, for ease of illustration, some components of the first to third pixels PX1 to PX3 are omitted.

Referring to FIGS. 1, 2, 7, and 9, one row line may include first to sixth lines L1 to L6. The first line L1 may be connected to the transfer lines TG1_1 of the first regions SP1_1 of the first sub-pixels SP1 of the first to third pixels PX1 to PX3 and may be connected to the transfer lines TG2_1 of the second regions SP2_1 of the second sub-pixels SP2 of the first to third pixels PX1 to PX3. The first line L1 may activate the first regions SP1_1 and SP2_1 of the first and second sub-pixels SP1 and SP2, for example, the photo detectors PD of the left side.

The second line L2 may be connected to the transfer lines TG1_2 of the second regions SP1_2 of the first sub-pixels SP1 of the first to third pixels PX1 to PX3 and may be connected to the transfer lines TG2_2 of the second regions SP2_2 of the second sub-pixels SP2 of the first to third pixels PX1 to PX3. The second line L2 may activate the second regions SP1_2 and SP2_2 of the first and second sub-pixels SP1 and SP2, for example, the photo detectors PD of the right side.

The third line L3 may be connected to the transfer lines TG3_1 of the first regions SP3_1 of the third sub-pixels SP3 of the first to third pixels PX1 to PX3. The third line L3 may activate the first regions SP3_1 of the third sub-pixels SP3, for example, the photo detectors PD of the left side.

The fourth line L4 may be connected to the transfer lines TG4_1 of the first regions SP4_1 of the fourth sub-pixels SP4 of the first to third pixels PX1 to PX3. The fourth line L4 may activate the first regions SP4_1 of the fourth sub-pixels SP4, for example, the photo detectors PD of the left side.

The fifth line L5 may be connected to the transfer lines TG3_2 of the second regions SP3_2 of the third sub-pixels SP3 of the first to third pixels PX1 to PX3 and may be connected to the transfer lines TG4_2 of the second regions SP4_2 of the fourth sub-pixels SP4 of the first to third pixels PX1 to PX3. The fifth line L5 may activate the second regions SP3_2 and SP4_2 of the third and fourth sub-pixels SP3 and SP4, for example, the photo detectors PD of the right side.

The sixth lines L6 may be connected in common with the first to third pixels PX1 to PX3. The sixth lines L6 may include a line that transfers the reset signal RG, a line that transfers the dynamic conversion gain signal DCG, and a line that transfers the selection signal SEL.

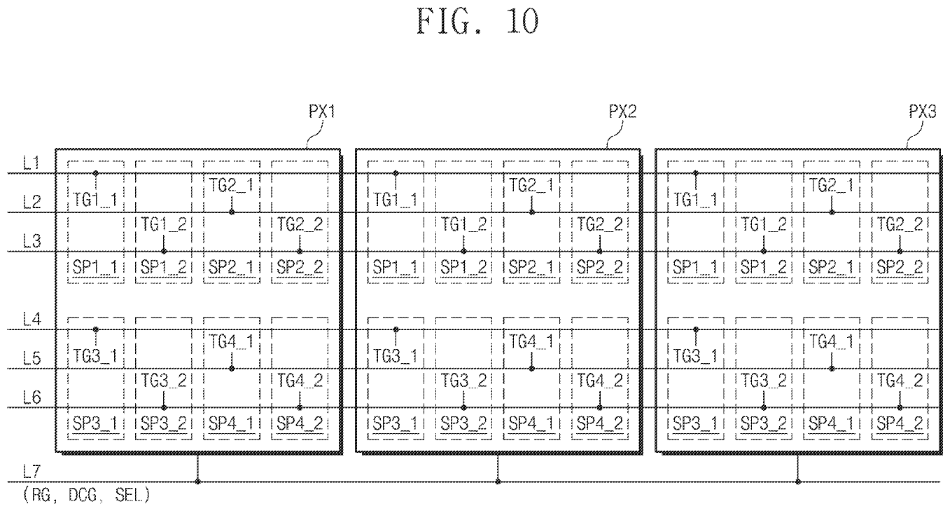

FIG. 10 illustrates a fifth example in which the first to third pixels PX1 to PX3 belonging to the same row are connected to lines of a corresponding row line. In an embodiment, the camera module 100 implemented in the wire structure of FIG. 10 may generate the HCG auto focus signal based on the 5th, 6th, 9th, and 10th cases C5, C6, C9, and C10 of FIG. 7. As in the first example E1 illustrated in FIG. 3, for ease of illustration, some components of the first to third pixels PX1 to PX3 are omitted.

Referring to FIGS. 1, 2, 7, and 10, one row line may include first to sixth lines L1 to L7. The first line L1 may be connected to the transfer lines TG1_1 of the first regions SP1_1 of the first sub-pixels SP1 of the first to third pixels PX1 to PX3. The first line L1 may activate the first regions SP1_1 of the first sub-pixels SP1, for example, the photo detectors PD of the left side.

The second line L2 may be connected to the transfer lines TG2_1 of the first regions SP2_1 of the second sub-pixels SP2 of the first to third pixels PX1 to PX3. The second line L2 may activate the first regions SP2_1 of the second sub-pixels SP2, for example, the photo detectors PD of the left side.

The third line L3 may be connected to the transfer lines TG1_2 of the second regions SP1_2 of the first sub-pixels SP1 of the first to third pixels PX1 to PX3 and may be connected to the transfer lines TG2_2 of the second regions SP2_2 of the second sub-pixels SP2 of the first to third pixels PX1 to PX3. The third line L3 may activate the second regions SP1_2 and SP2_2 of the first and second sub-pixels SP1 and SP2, for example, the photo detectors PD of the right side.

The fourth line L4 may be connected to the transfer lines TG3_1 of the first regions SP3_1 of the third sub-pixels SP3 of the first to third pixels PX1 to PX3. The fourth line L4 may activate the first regions SP3_1 of the third sub-pixels SP3, for example, the photo detectors PD of the left side.

The fifth line L5 may be connected to the transfer lines TG4_1 of the first regions SP4_1 of the fourth sub-pixels SP4 of the first to third pixels PX1 to PX3. The fifth line L5 may activate the first regions SP4_1 of the fourth sub-pixels SP4, for example, the photo detectors PD of the left side.

The sixth line L6 may be connected to the transfer lines TG3_2 of the second regions SP3_2 of the third sub-pixels SP3 of the first to third pixels PX1 to PX3 and may be connected to the transfer lines TG4_2 of the second regions SP4_2 of the fourth sub-pixels SP4 of the first to third pixels PX1 to PX3. The sixth line L6 may activate the second regions SP3_2 and SP4_2 of the third and fourth sub-pixels SP3 and SP4, for example, the photo detectors PD of the right side.

The seventh lines L7 may be connected in common with the first to third pixels PX1 to PX3. The seventh lines L7 may include a line that transfers the reset signal RG, a line that transfers the dynamic conversion gain signal DCG, and a line that transfers the selection signal SEL.

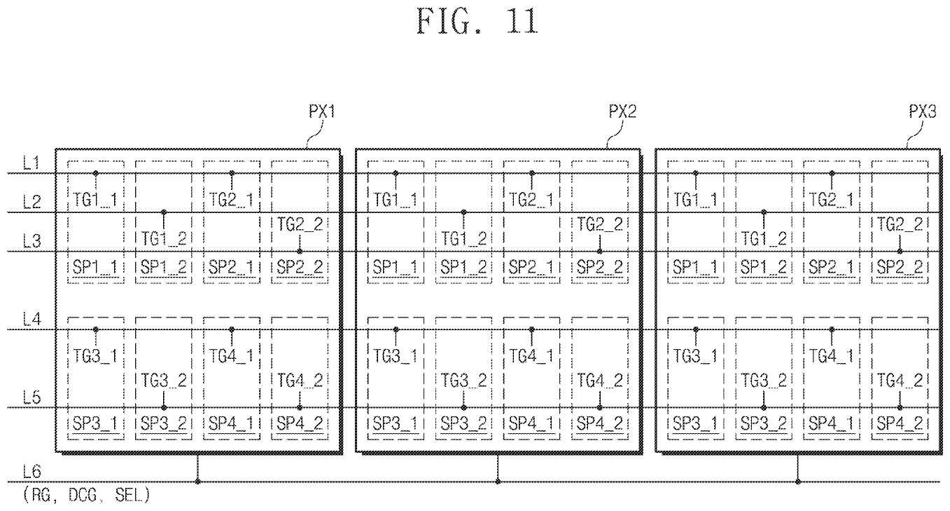

FIG. 11 illustrates a sixth example in which the first to third pixels PX1 to PX3 belonging to the same row are connected to lines of a corresponding row line. In an embodiment, the camera module 100 implemented in the wire structure of FIG. 11 may generate the HCG auto focus signal based on the 12th and 13th cases C12 and C13 of FIG. 7. As in the first example E1 illustrated in FIG. 3, for ease of illustration, some components of the first to third pixels PX1 to PX3 are omitted.

Referring to FIGS. 1, 2, 7, and 11, one row line may include first to sixth lines L1 to L6. The first line L1 may be connected to the transfer lines TG1_1 of the first regions SP1_1 of the first sub-pixels SP1 of the first to third pixels PX1 to PX3 and may be connected to the transfer lines TG2_1 of the first regions SP2_1 of the second sub-pixels SP2 of the first to third pixels PX1 to PX3. The first line L1 may activate the first regions SP1_1 and SP2_1 of the first sub-pixels SP1 and the second sub pixels SP2, for example, the photo detectors PD of the left side.

The second line L2 may be connected to the transfer lines TG2_1 of the second regions SP1_2 of the first sub-pixels SP1 of the first to third pixels PX1 to PX3. The second line L2 may activate the second regions SP1_2 of the first sub-pixels SP1, for example, the photo detectors PD of the right side.

The third line L3 may be connected to the transfer lines TG2_2 of the second regions SP2_2 of the second sub-pixels SP2 of the first to third pixels PX1 to PX3. The third line L3 may activate the second regions SP2_2 of the second sub-pixels SP2, for example, the photo detectors PD of the right side.

The fourth line L4 may be connected to the transfer lines TG3_1 of the first regions SP3_1 of the third sub-pixels SP3 of the first to third pixels PX1 to PX3 and may be connected to the transfer lines TG4_1 of the first regions SP4_1 of the fourth sub-pixels SP4 of the first to third pixels PX1 to PX3. The fourth line L4 may activate the first regions SP3_1 and SP4_1 of the third and fourth sub-pixels SP3 and SP4, for example, the photo detectors PD of the left side.

The fifth line L5 may be connected to the transfer lines TG3_2 of the second regions SP3_2 of the third sub-pixels SP3 of the first to third pixels PX1 to PX3 and may be connected to the transfer lines TG4_2 of the second regions SP4_2 of the fourth sub-pixels SP4 of the first to third pixels PX1 to PX3. The fifth line L5 may activate the second regions SP3_2 and SP4_2 of the third and fourth sub-pixels SP3 and SP4, for example, the photo detectors PD of the right side.

The sixth lines L6 may be connected in common with the first to third pixels PX1 to PX3. The sixth lines L6 may include a line that transfers the reset signal RG, a line that transfers the dynamic conversion gain signal DCG, and a line that transfers the selection signal SEL.

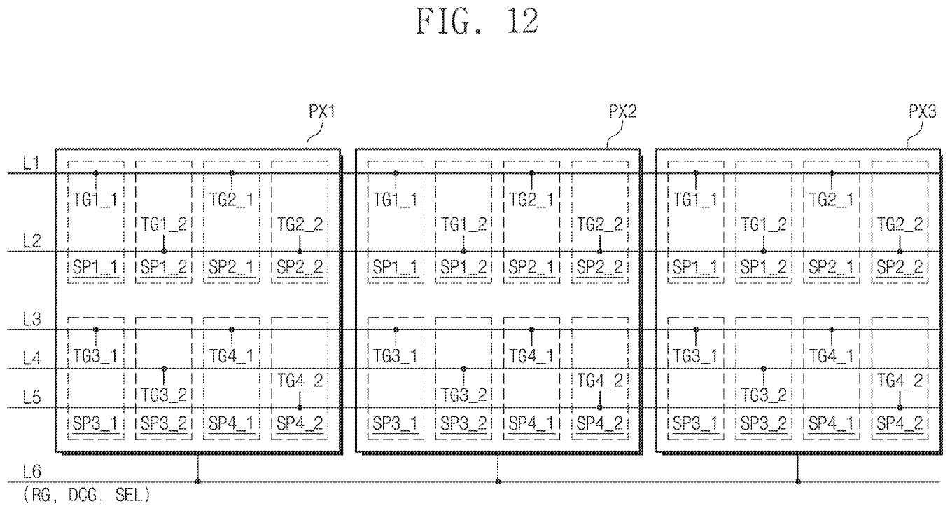

FIG. 12 illustrates a seventh example in which the first to third pixels PX1 to PX3 belonging to the same row are connected to lines of a corresponding row line. In an embodiment, the camera module 100 implemented in the wire structure of FIG. 12 may generate the HCG auto focus signal based on the 14th and 15th cases C14 and C15 of FIG. 7. As in the first example E1 illustrated in FIG. 3, for ease of illustration, some components of the first to third pixels PX1 to PX3 are omitted.

Referring to FIGS. 1, 2, 7, and 12, one row line may include first to sixth lines L1 to L6. The first line L1 may be connected to the transfer lines TG1_1 of the first regions SP1_1 of the first sub-pixels SP1 of the first to third pixels PX1 to PX3 and may be connected to the transfer lines TG2_1 of the second regions SP2_1 of the second sub-pixels SP2 of the first to third pixels PX1 to PX3. The first line L1 may activate the first regions SP1_1 and SP2_1 of the first and second sub-pixels SP1 and SP2, for example, the photo detectors PD of the left side.

The second line L2 may be connected to the transfer lines TG1_2 of the second regions SP1_2 of the first sub-pixels SP1 of the first to third pixels PX1 to PX3 and may be connected to the transfer lines TG2_2 of the second regions SP2_2 of the second sub-pixels SP2 of the first to third pixels PX1 to PX3. The second line L2 may activate the second regions SP1_2 and SP2_2 of the first and second sub-pixels SP1 and SP2, for example, the photo detectors PD of the right side.

The third line L3 may be connected to the transfer lines TG3_1 of the first regions SP3_1 of the third sub-pixels SP3 of the first to third pixels PX1 to PX3 and may be connected to the transfer lines TG4_1 of the first regions SP4_1 of the fourth sub-pixels SP4. The third line L3 may activate the first regions SP3_1 and SP4_1 of the third sub-pixels SP3 and the fourth sub-pixels SP4, for example, the photo detectors PD of the left side.

The fourth line L4 may be connected to the transfer lines TG3_2 of the second regions SP3_2 of the third sub-pixels SP3 of the first to third pixels PX1 to PX3. The fourth line L4 may activate the second regions SP3_2 of the third sub-pixels SP3, for example, the photo detectors PD of the right side.

The fifth line L5 may be connected to the transfer lines TG4_2 of the second regions SP4_2 of the fourth sub-pixels SP4 of the first to third pixels PX1 to PX3. The fifth line L5 may activate the second regions SP4_2 of the fourth sub-pixels SP4, for example, the photo detectors PD of the right side.

The sixth lines L6 may be connected in common with the first to third pixels PX1 to PX3. The sixth lines L6 may include a line that transfers the reset signal RG, a line that transfers the dynamic conversion gain signal DCG, and a line that transfers the selection signal SEL.

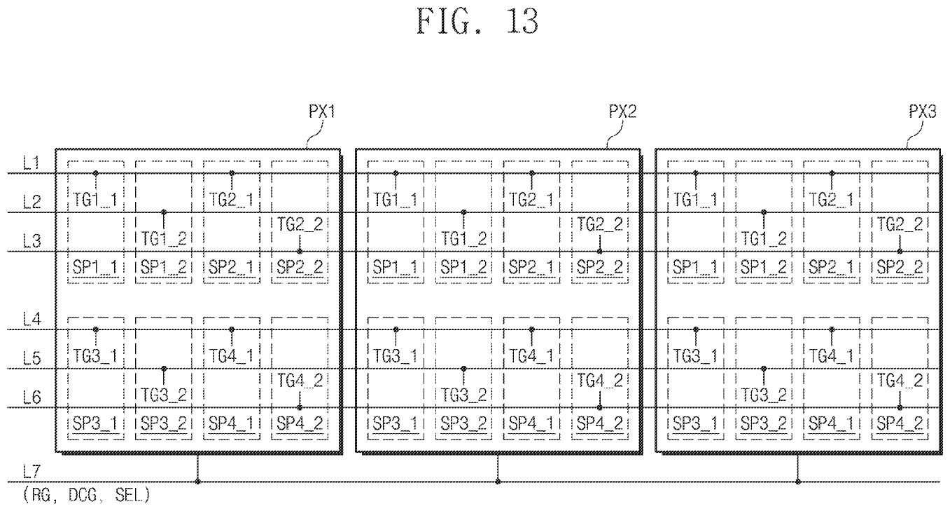

FIG. 13 illustrates an eighth example in which the first to third pixels PX1 to PX3 belonging to the same row are connected to lines of a corresponding row line. In an embodiment, the camera module 100 implemented in the wire structure of FIG. 13 may generate the HCG auto focus signal based on the 16th, 17th, 20th, and 21st cases C16, C17, C20, and C21 of FIG. 7. As in the first example E1 illustrated in FIG. 3, for ease of illustration, some components of the first to third pixels PX1 to PX3 are omitted.

Referring to FIGS. 1, 2, 7, and 13, one row line may include first to seventh lines L1 to L7. The first line L1 may be connected to the transfer lines TG1_1 of the first regions SP1_1 of the first sub-pixels SP1 of the first to third pixels PX1 to PX3 and may be connected to the transfer lines TG2_1 of the first regions SP2_1 of the second sub-pixels SP2 of the first to third pixels PX1 to PX3. The first line L1 may activate the first regions SP1_1 and SP2_1 of the first sub-pixels SP1 and the second sub-pixels SP2, for example, the photo detectors PD of the left side.

The second line L2 may be connected to the transfer lines TG1_2 of the second regions SP1_2 of the first sub-pixels SP1 of the first to third pixels PX1 to PX3. The second line L2 may activate the second regions SP1_2 of the first sub-pixels SP1, for example, the photo detectors PD of the right side.

The third line L3 may be connected to the transfer lines TG2_2 of the second regions SP2_2 of the second sub-pixels SP2 of the first to third pixels PX1 to PX3. The third line L3 may activate the second regions SP2_2 of the second sub-pixels SP2, for example, the photo detectors PD of the right side.

The fourth line L4 may be connected to the transfer lines TG3_1 of the first regions SP3_1 of the third sub-pixels SP3 of the first to third pixels PX1 to PX3 and may be connected to the first regions SP4_1 of the fourth sub-pixels SP4 of the first to third pixels PX1 to PX3. The fourth line L4 may activate the first regions SP3_1 and SP4_1 of the third sub-pixels SP3 and the fourth sub-pixels SP4, for example, the photo detectors PD of the left side.

The fifth line L5 may be connected to the transfer lines TG3_2 of the second regions SP3_2 of the third sub-pixels SP3 of the first to third pixels PX1 to PX3. The fifth line L5 may activate the second regions SP3_2 of the third sub-pixels SP3, for example, the photo detectors PD of the right side.

The sixth line L6 may be connected to the transfer lines TG4_2 of the second regions SP4_2 of the fourth sub-pixels SP4 of the first to third pixels PX1 to PX3. The sixth line L6 may activate the second regions SP4_2 of the fourth sub-pixels SP4, for example, the photo detectors PD of the right side.

The seventh lines L7 may be connected in common with the first to third pixels PX1 to PX3. The seventh lines L7 may include a line that transfers the reset signal RG, a line that transfers the dynamic conversion gain signal DCG, and a line that transfers the selection signal SEL.

In an embodiment, the camera module 100 implemented in the wire structure of FIG. 3 may generate the HCG auto focus signal based on the 7th, 8th, 11th, 18th, 19th, and 22nd C7, C8, C11, C18, C19, and C22 of FIG. 7.

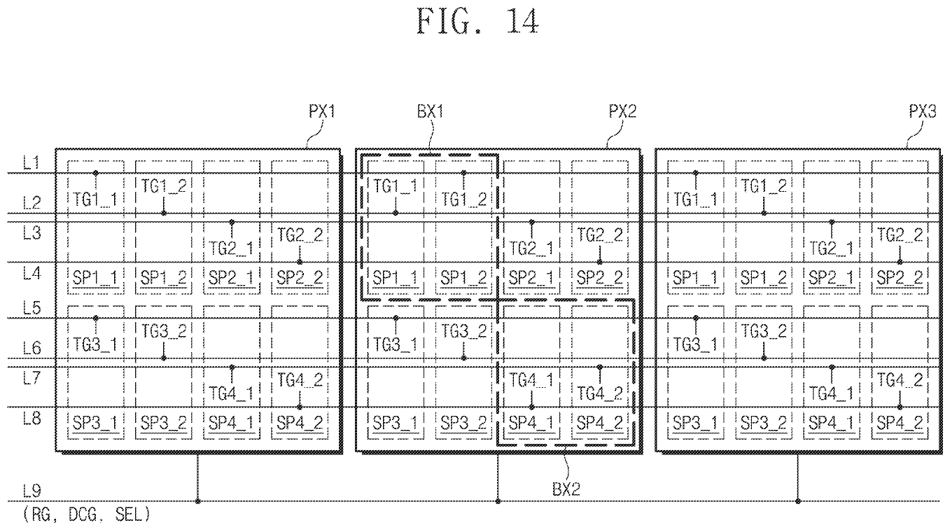

FIG. 14 illustrates a ninth example in which the first to third pixels PX1 to PX3 belonging to the same row are connected to lines of a corresponding row line. As in the first example E1 illustrated in FIG. 3, for ease of illustration, some components of the first to third pixels PX1 to PX3 are omitted.

Referring to FIGS. 1, 2, and 14, one row line may include first to ninth lines L1 to L9. The wire structure of FIG. 14 and the wire structure of FIG. 5 may differ from each other in portions corresponding to a first box BX1 and a second box BX2.

The first line L1 may be connected to the first pixel PX1, for example, the transfer lines TG1_1 of the first regions SP1_1 of the first sub-pixels SP1 of odd-numbered pixels in a row direction. Also, the first line L1 may be connected to the second pixel PX2, for example, the transfer lines TG1_2 of the second regions SP1_2 of the first sub-pixels SP1 of even-numbered pixels.

The second line L2 may be connected to the first pixel PX1, for example, the transfer lines TG1_2 of the second regions SP1_2 of the first sub-pixels SP1 of the odd-numbered pixels in the row direction. Also, the second line L2 may be connected to the second pixel PX2, for example, the transfer lines TG1_1 of the first regions SP1_1 of the first sub-pixels SP1 of the even-numbered pixels in the row direction.

The third line L3 may be connected to the transfer lines TG2_1 of the first regions SP2_1 of the second sub-pixels SP2 of the first to third pixels PX1 to PX3. The third line L3 may activate the first regions SP2_1 of the second sub-pixels SP2, for example, the photo detectors PD of the left side.

The fourth line L4 may be connected to the transfer lines TG2_2 of the second regions SP2_2 of the second sub-pixels SP2 of the first to third pixels PX1 to PX3. The fourth line L4 may activate the second regions SP2_2 of the second sub-pixels SP2, for example, the photo detectors PD of the right side.

The fifth line L5 may be connected to the transfer lines TG3_1 of the first regions SP3_1 of the third sub-pixels SP3 of the first to third pixels PX1 to PX3. The fifth line L5 may activate the first regions SP3_1 of the third sub-pixels SP3, for example, the photo detectors PD of the left side.

The sixth line L6 may be connected to the transfer lines TG3_2 of the second regions SP3_2 of the third sub-pixels SP3 of the first to third pixels PX1 to PX3. The sixth line L6 may activate the second regions SP3_2 of the third sub-pixels SP3, for example, the photo detectors PD of the right side.

The seventh line L7 may be connected to the first pixel PX1, for example, the transfer lines TG4_1 of the first regions SP4_1 of the fourth sub-pixels SP4 of the odd-numbered pixels in the row direction. Also, the seventh line L7 may be connected to the second pixel PX2, for example, the transfer lines TG4_2 of the second regions SP4_2 of the fourth sub-pixels SP4 of the even-numbered pixels in the row direction.

The eighth line L8 may be connected to the first pixel PX1, for example, the transfer lines TG4_2 of the second regions SP4_2 of the fourth sub-pixels SP4 of the odd-numbered pixels in the row direction. Also, the eighth line L8 may be connected to the second pixel PX2, for example, the transfer lines TG4_1 of the first regions SP4_1 of the fourth sub-pixels SP4 of the even-numbered pixels in the row direction.

The ninth lines L9 may be connected in common with the first to third pixels PX1 to PX3. The ninth lines L9 may include a line that transfers the reset signal RG, a line that transfers the dynamic conversion gain signal DCG, and a line that transfers the selection signal SEL.

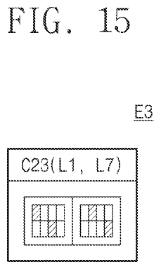

FIG. 15 illustrates a 23rd case C23 of the third example E3 in which the digital HCG auto focus signal is generated based on the wire structure of FIG. 14.

Referring to FIGS. 1, 2, 14, and 15, a first digital HCG auto focus signal may be generated from output signals of the left photo detectors PD, which respectively correspond to the first sub-pixel SP1 and the fourth sub-pixel SP4, from among the photo detectors PD of odd-numbered pixels in the row direction, for example, the first pixel PX and the third pixel PX3.

A second digital HCG auto focus signal may be generated from output signals of the right photo detectors PD, which respectively correspond to the first sub-pixel SP1 and the fourth sub-pixel SP4, from among the photo detectors PD of even-numbered pixels in the row direction, for example, the second pixel PX2. The logic circuit 160 may perform phase detection auto focusing based on the first and second digital HCG auto focus signals. Alternatively, the logic circuit 160 may output the first digital HCG auto focus signal and the second digital HCG auto focus signal as information for auto focusing.

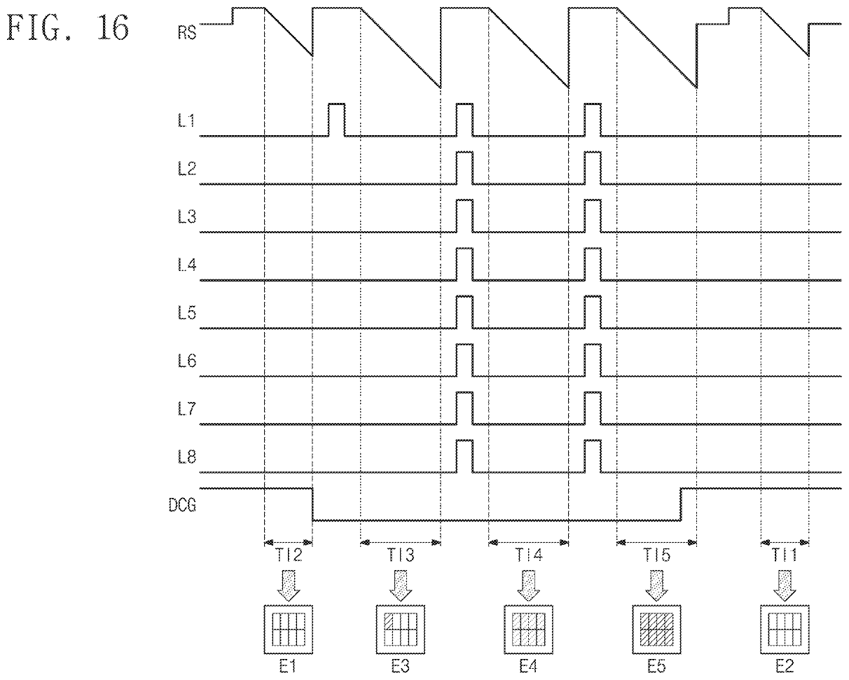

FIG. 16 illustrates an example in which the camera module 100 captures the image data ID of the pixels PX1 to PX3 in one row based on one of the wire structures of FIGS. 5 and 8 to 14.

Referring to FIGS. 1, 2, and 16, the camera module 100 may capture the image data ID of the pixels PX1 to PX3 in one row based on first to fifth time intervals TI1 to TI5.

Unlike the example illustrated in FIG. 6, in the example illustrated in FIG. 16, the camera module 100 may capture signals in the order of the second time interval TI2, the third time interval TI3, the fourth time interval TI4, the fifth time interval TI5, and the first time interval TH.

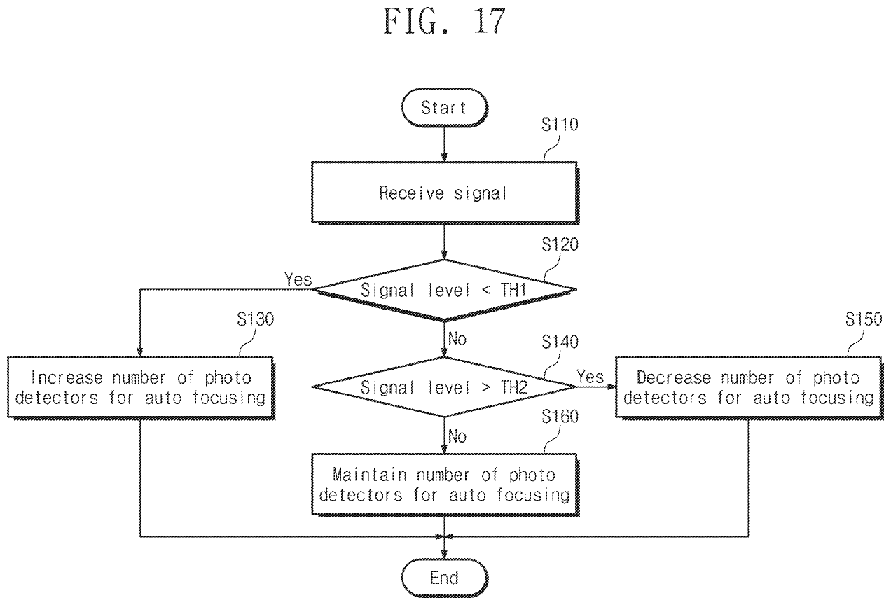

FIG. 17 illustrates an example of an operating method of the camera module 100 implemented in the wire structure of FIG. 5. Referring to FIGS. 1, 2, 5, and 17, in operation S110, the logic circuit 160 of the camera module 100 may receive a digital HCG auto focus signal. In operation S120, the logic circuit 160 of the camera module 100 may determine whether a level of the digital HCG auto focus signal is smaller than a first threshold TH1.

When the level of the digital HCG auto focus signal is smaller than the first threshold TH1, in operation S130, the logic circuit 160 of the camera module 100 may increase the number of photo detectors PD to be used for auto focusing. For example, based on the cases illustrated in FIG. 7, the logic circuit 160 may increase the number of photo detectors PD to be used to generate the digital HCG auto focus signal.

When the level of the digital HCG auto focus signal is not smaller than (e.g., equal to or more than) the first threshold TH1, in operation S140, the logic circuit 160 of the camera module 100 may determine whether the level of the digital HCG auto focus signal is greater than a second threshold TH2. The second threshold TH2 may be greater than the first threshold TH1.

When the level of the digital HCG auto focus signal is greater than the second threshold TH2, in operation S150, the logic circuit 160 of the camera module 100 may decrease the number of photo detectors PD to be used for auto focusing. For example, based on the case illustrated in FIG. 7, the logic circuit 160 may decrease the number of photo detectors PD to be used to generate the digital HCG auto focus signal.

When the level of the digital HCG auto focus signal is not greater than the second threshold TH2, in operation S160, the logic circuit 160 of the camera module 100 may maintain the number of photo detectors PD to be used for auto focusing. That is, the camera module 100 may increase the accuracy of auto focusing by adaptively adjusting the number of photo detectors PD to be used for auto focusing at each pixel PX, based on the intensity of incident light.

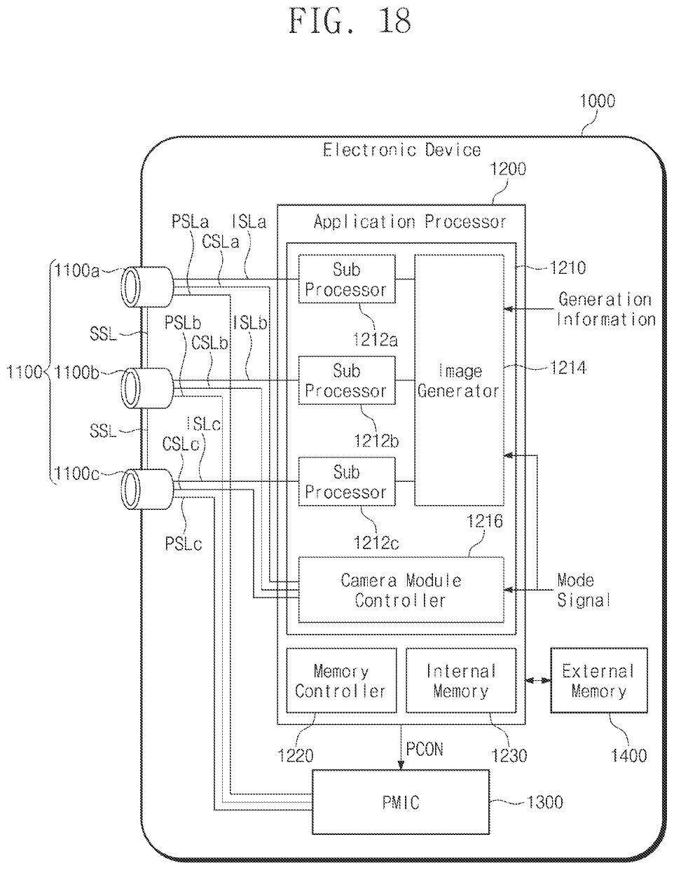

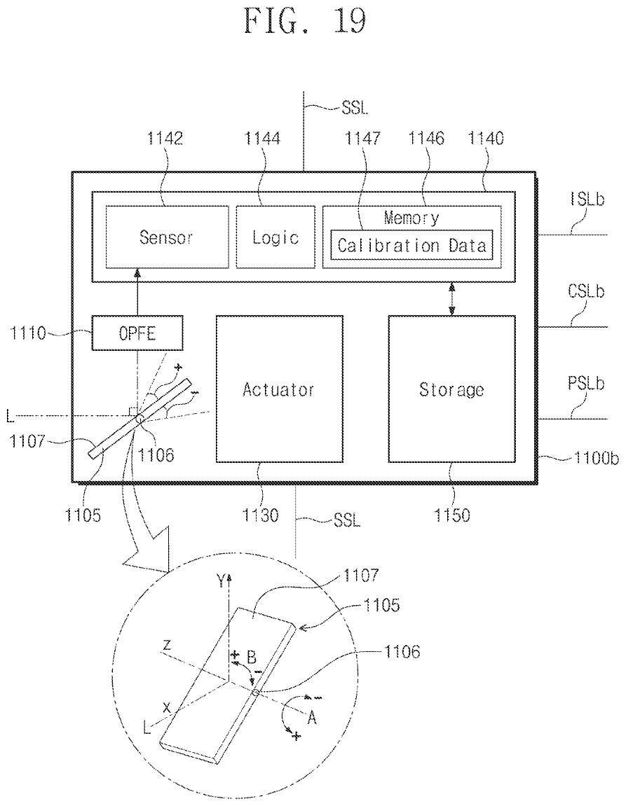

FIG. 18 is a block diagram of an electronic device including a multi-camera module. FIG. 19 is a detailed block diagram of a camera module of FIG. 18.

Referring to FIG. 18, an electronic device 1000 may include a camera module group 1100, an application processor 1200, a PMIC 1300, and an external memory 1400.

The camera module group 1100 may include a plurality of camera modules 1100a, 1100b, and 1100c. An embodiment in which three camera modules 1100a, 1100b, and 1100c are disposed is illustrated in FIG. 18. However, embodiments are not limited thereto. In some embodiments, the camera module group 1100 may be modified to include only two camera modules. Also, in some embodiments, the camera module group 1100 may be modified to include “i” camera modules (i being a natural number of 4 or more). In an embodiment, each of the plurality of camera modules 1100a, 1100b, and 1100c of the camera module group 1100 may include the camera module 100 of FIG. 1.

Below, a detailed configuration of the camera module 1100b will be more fully described with reference to FIG. 19. It is to be understood that the following description may be equally applied to the remaining camera modules 1100a and 1100c.

Referring to FIG. 19, the camera module 1100b may include a prism 1105, an optical path folding element (OPFE) 1110, an actuator 1130, an image sensing device 1140, and a storage unit 1150.

The prism 1105 may include a reflecting plane 1107 made of a light reflecting material and may change a path of a light “L” incident from outside the camera module 1100b.

In some embodiments, the prism 1105 may change a path of the light “L” incident in a first direction “X” to a second direction “Y” perpendicular to the first direction “X”. Also, the prism 1105 may change the path of the light “L” incident in the first direction “X” to the second direction “Y” perpendicular to the first direction “X” by rotating the reflecting plane 1107 of the light reflecting material in direction “A” about a central axis 1106 or rotating the central axis 1106 in direction “B”. In this case, the OPFE 1110 may move in a third direction “Z” perpendicular to the first direction “X” and the second direction “Y”.

In some embodiments, as illustrated, a maximum rotation angle of the prism 1105 in direction “A” may be equal to or smaller than about 15 degrees in a positive A direction and may be greater than about 15 degrees in a negative A direction. However, embodiments are not limited thereto.

In some embodiments, the prism 1105 may move within about 20 degrees in a positive or negative B direction, between about 10 degrees and about 20 degrees, or between about 15 degrees and about 20 degrees. Here, the prism 1105 may move at the same angle in the positive or negative B direction or may move at a similar angle within about 1 degree.

In some embodiments, the prism 1105 may move the reflecting plane 1107 of the light reflecting material in the third direction (e.g., a Z direction) parallel to a direction in which the central axis 1106 extends.

For example, the OPFE 1110 may include optical lenses composed of “j” groups (j being a natural number). Here, “j” lens may move in the second direction “Y” to change an optical zoom ratio of the camera module 1100b. For example, when a default optical zoom ratio of the camera module 1100b is “Z”, the optical zoom ratio of the camera module 1100b may be changed to an optical zoom ratio of 3Z or 5Z or more by moving “j” optical lens included in the OPFE 1110.

The actuator 1130 may move the OPFE 1110 or an optical lens (hereinafter referred to as an “optical lens”) to a specific location. For example, the actuator 1130 may adjust a location of an optical lens such that an image sensor 1142 is placed at a focal length of the optical lens for accurate sensing.

The image sensing device 1140 may include the image sensor 1142, control logic 1144, and a memory 1146. The image sensor 1142 may sense an image of a sensing target by using the light “L” provided through an optical lens.

The control logic 1144 may control overall operations of the camera module 1100b. For example, the control logic 1144 may control an operation of the camera module 1100b based on a control signal provided through a control signal line CSLb.

The memory 1146 may store information used for an operation of the camera module 1100b, such as, for example, calibration data 1147. The calibration data 1147 may include information used for the camera module 1100b to generate image data by using the light “L” provided from outside the camera module 1100b. The calibration data 1147 may include, for example, information about the degree of rotation described above, information about a focal length, information about an optical axis, etc. In the case where the camera module 1100b is implemented in the form of a multi-state camera in which a focal length varies depending on a location of an optical lens, the calibration data 1147 may include a focal length value for each location (or state) of the optical lens and information about auto focusing.

The storage unit 1150 may store image data sensed through the image sensor 1142. The storage unit 1150 may be disposed outside the image sensing device 1140 and may be implemented in a shape where the storage unit 1150 and a sensor chip constituting the image sensing device 1140 are stacked. In some embodiments, the storage unit 1150 may be implemented with an electrically erasable programmable read only memory (EEPROM). However, embodiments are not limited thereto.

Referring to FIGS. 18 and 19, in some embodiments, each of the plurality of camera modules 1100a, 1100b, and 1100c may include the actuator 1130. As such, the same calibration data 1147 or different calibration data 1147 may be included in the plurality of camera modules 1100a, 1100b, and 1100c depending on operations of the actuators 1130 therein.

In some embodiments, one camera module (e.g., 1100b) among the plurality of camera modules 1100a, 1100b, and 1100c may be a folded lens shape in which the prism 1105 and the OPFE 1110 described above are included, and the remaining camera modules (e.g., 1100a and 1100c) may be a vertical shape in which the prism 1105 and the OPFE 1110 described above are not included. However, embodiments are not limited thereto.

In some embodiments, one camera module (e.g., 1100c) among the plurality of camera modules 1100a, 1100b, and 1100c may be, for example, a vertical shape of depth camera extracting depth information by using an infrared (IR) ray. In this case, the application processor 1200 may merge image data provided from the depth camera and image data provided from any other camera module (e.g., 1100a or 1100b) and may generate a three-dimensional (3D) depth image.

In some embodiments, at least two camera modules (e.g., 1100a and 1100b) among the plurality of camera modules 1100a, 1100b, and 1100c may have different fields of view. In this case, the at least two camera modules (e.g., 1100a and 1100b) among the plurality of camera modules 1100a, 1100b, and 1100c may include different optical lens. However, embodiments are not limited thereto.

Also, in some embodiments, fields of view of the plurality of camera modules 1100a, 1100b, and 1100c may be different. In this case, the plurality of camera modules 1100a, 1100b, and 1100c may include different optical lens. However, embodiments are not limited thereto.

In some embodiments, the plurality of camera modules 1100a, 1100b, and 1100c may be physically separated from each other. That is, in some embodiments, the plurality of camera modules 1100a, 1100b, and 1100c do not use a sensing area of one image sensor 1142, but rather, the plurality of camera modules 1100a, 1100b, and 1100c may include independent image sensors 1142 therein, respectively.

Referring again to FIG. 18, the application processor 1200 may include an image processing device 1210, a memory controller 1220, and an internal memory 1230. The application processor 1200 may be implemented to be separated from the plurality of camera modules 1100a, 1100b, and 1100c. For example, the application processor 1200 and the plurality of camera modules 1100a, 1100b, and 1100c may be implemented with separate semiconductor chips.

The image processing device 1210 may include a plurality of sub image processors 1212a, 1212b, and 1212c, an image generator 1214, and a camera module controller 1216.

The image processing device 1210 may include the plurality of sub image processors 1212a, 1212b, and 1212c, the number of which corresponds to the number of the plurality of camera modules 1100a, 1100b, and 1100c.

Image data respectively generated from the camera modules 1100a, 1100b, and 1100c may be respectively provided to the corresponding sub image processors 1212a, 1212b, and 1212c through separated image signal lines ISLa, ISLb, and ISLc. For example, the image data generated from the camera module 1100a may be provided to the sub image processor 1212a through the image signal line ISLa, the image data generated from the camera module 1100b may be provided to the sub image processor 1212b through the image signal line ISLb, and the image data generated from the camera module 1100c may be provided to the sub image processor 1212c through the image signal line ISLc. This image data transmission may be performed, for example, by using a camera serial interface (CSI) based on the MIPI (Mobile Industry Processor Interface). However, embodiments are not limited thereto.

In some embodiments, one sub image processor may be disposed to correspond to a plurality of camera modules. For example, the sub image processor 1212a and the sub image processor 1212c may be integrally implemented, and not separated from each other as illustrated in FIG. 18. In this case, one of the pieces of image data respectively provided from the camera module 1100a and the camera module 1100c may be selected through a selection element (e.g., a multiplexer), and the selected image data may be provided to the integrated sub image processor.

The image data respectively provided to the sub image processors 1212a, 1212b, and 1212c may be provided to the image generator 1214. The image generator 1214 may generate an output image by using the image data respectively provided from the sub image processors 1212a, 1212b, and 1212c, depending on image generation information “Generation Information” or a mode signal.

For example, the image generator 1214 may generate the output image by merging at least a portion of the image data respectively generated from the camera modules 1100a, 1100b, and 1100c having different fields of view, depending on the image generation information “Generation Information” or the mode signal. Also, the image generator 1214 may generate the output image by selecting one of the image data respectively generated from the camera modules 1100a, 1100b, and 1100c having different fields of view, depending on the image generation information “Generation Information” or the mode signal.

In some embodiments, the image generation information “Generation Information” may include a zoom signal or a zoom factor. Also, in some embodiments, the mode signal may be, for example, a signal based on a mode selected from a user.

In the case where the image generation information “Generation Information” is the zoom signal (or zoom factor) and the camera modules 1100a, 1100b, and 1100c have different visual fields (or fields of view), the image generator 1214 may perform different operations depending on a type of the zoom signal. For example, in the case where the zoom signal is a first signal, the image generator 1214 may merge the image data output from the camera module 1100a and the image data output from the camera module 1100c and may generate the output image by using the merged image signal and the image data output from the camera module 1100b that is not used in the merging operation. In the case where the zoom signal is a second signal different from the first signal, without the image data merging operation, the image generator 1214 may select one of the image data respectively output from the camera modules 1100a, 1100b, and 1100c and may output the selected image data as the output image. However, embodiments are not limited thereto. For example, according to embodiments, the manner of processing image data may be modified without limitation if necessary.

In some embodiments, the image generator 1214 may generate merged image data having an increased dynamic range by receiving a plurality of image data of different exposure times from at least one of the plurality of sub image processors 1212a, 1212b, and 1212c, and performing high dynamic range (HDR) processing on the plurality of image data.

The camera module controller 1216 may provide control signals to the camera modules 1100a, 1100b, and 1100c, respectively. The control signals generated from the camera module controller 1216 may be respectively provided to the corresponding camera modules 1100a, 1100b, and 1100c through control signal lines CSLa, CSLb, and CSLc separated from each other.

One of the plurality of camera modules 1100a, 1100b, and 1100c may be designated as a master camera (e.g., 1100b) depending on the image generation information “Generation Information” including a zoom signal or the mode signal, and the remaining camera modules (e.g., 1100a and 1100c) may be designated as a slave camera. The above designation information may be included in the control signals, and the control signals including the designation information may be respectively provided to the corresponding camera modules 1100a, 1100b, and 1100c through the control signal lines CSLa, CSLb, and CSLc separated from each other.

Camera modules operating as a master and a slave may be changed depending on the zoom factor or an operating mode signal. For example, in the case where the field of view of the camera module 1100a is wider than the field of view of the camera module 1100b and the zoom factor indicates a low zoom ratio, the camera module 1100b may operate as a master, and the camera module 1100a may operate as a slave. In contrast, in the case where the zoom factor indicates a high zoom ratio, the camera module 1100a may operate as a master, and the camera module 1100b may operate as a slave.

In some embodiments, the control signal provided from the camera module controller 1216 to each of the camera modules 1100a, 1100b, and 1100c may include a sync enable signal. For example, in the case where the camera module 1100b is used as a master camera and the camera modules 1100a and 1100c are used as a slave camera, the camera module controller 1216 may transmit the sync enable signal to the camera module 1100b. The camera module 1100b that is provided with sync enable signal may generate a sync signal based on the provided sync enable signal and may provide the generated sync signal to the camera modules 1100a and 1100c through a sync signal line SSL. The camera module 1100b and the camera modules 1100a and 1100c may be synchronized with the sync signal to transmit image data to the application processor 1200.

In some embodiments, the control signal provided from the camera module controller 1216 to each of the camera modules 1100a, 1100b, and 1100c may include mode information according to the mode signal. Based on the mode information, the plurality of camera modules 1100a, 1100b, and 1100c may operate in a first operating mode and a second operating mode with regard to a sensing speed.

In the first operating mode, the plurality of camera modules 1100a, 1100b, and 1100c may generate image signals at a first speed (e.g., may generate image signals of a first frame rate), may encode the image signals at a second speed (e.g., may encode the image signal of a second frame rate higher than the first frame rate), and transmit the encoded image signals to the application processor 1200. In this case, the second speed may be about 30 times or less than the first speed.

The application processor 1200 may store the received image signals, that is, the encoded image signals, in the internal memory 1230 provided therein or the external memory 1400 placed outside the application processor 1200. Afterwards, the application processor 1200 may read and decode the encoded image signals from the internal memory 1230 or the external memory 1400 and may display image data generated based on the decoded image signals. For example, the corresponding one among sub image processors 1212a, 1212b, and 1212c of the image processing device 1210 may perform decoding and may also perform image processing on the decoded image signal.

In the second operating mode, the plurality of camera modules 1100a, 1100b, and 1100c may generate image signals at a third speed (e.g., may generate image signals of a third frame rate lower than the first frame rate) and transmit the image signals to the application processor 1200. The image signals provided to the application processor 1200 may be signals that are not encoded. The application processor 1200 may perform image processing on the received image signals or may store the image signals in the internal memory 1230 or the external memory 1400.

The PMIC 1300 may supply powers, for example, power supply voltages to the plurality of camera modules 1100a, 1100b, and 1100c, respectively. For example, under control of the application processor 1200, the PMIC 1300 may supply a first power to the camera module 1100a through a power signal line PSLa, may supply a second power to the camera module 1100b through a power signal line PSLb, and may supply a third power to the camera module 1100c through a power signal line PSLc.

In response to a power control signal PCON from the application processor 1200, the PMIC 1300 may generate a power corresponding to each of the plurality of camera modules 1100a, 1100b, and 1100c and may adjust a level of the power. The power control signal PCON may include a power adjustment signal for each operating mode of the plurality of camera modules 1100a, 1100b, and 1100c. For example, the operating mode may include a low-power mode. In this case, the power control signal PCON may include information about a camera module operating in the low-power mode and a set power level. Levels of the powers respectively provided to the plurality of camera modules 1100a, 1100b, and 1100c may be identical to each other or may be different from each other. Also, a level of a power may be dynamically changed.

In the above embodiments, components are described by using the terms “first”, “second”, “third”, etc. It will be understood that the terms “first,” “second,” “third,” etc. are used herein to distinguish one element from another, and the elements are not limited by these terms. Thus, a “first” element in an embodiment may be described as a “second” element in another embodiment.

In the above embodiments, components are referenced by using blocks. The blocks may be implemented with various hardware devices, such as an integrated circuit, an application specific IC (ASIC), a field programmable gate array (FPGA), and a complex programmable logic device (CPLD), firmware driven in hardware devices, software such as an application, or a combination of a hardware device and software. Also, the blocks may include circuits implemented with semiconductor elements in an integrated circuit, or circuits functioning as an intellectual property (IP) block.

According to embodiments of the present disclosure, a camera module generates a signal for auto focusing by using photo detectors, the number of which is less than half of the number of photo detectors of one pixel. Accordingly, a camera module that prevents a signal for auto focusing from being saturated and performs auto focusing in a high dynamic range (HDR), and an operating method of the camera module, are provided.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A camera module, comprising:
a pixel array comprising a plurality of pixels arranged in a row,
wherein each of the pixels comprises a first sub-pixel, a second sub-pixel, a third sub-pixel, and a fourth sub-pixel;
a row driver connected to the pixels through a plurality of row lines;
an analog-to-digital conversion circuit connected to the pixels through a plurality of column lines, and configured to convert signals of the column lines into digital values; and
a logic circuit,
wherein each of the first sub-pixel, the second sub-pixel, the third sub-pixel, and the fourth sub-pixel comprises a first region and a second region,
wherein each of the first region and the second region comprises a photo detector,
wherein the analog-to-digital conversion circuit generates a first signal in response to the row driver activating signals of half or less of the photo detectors included in one pixel among the pixels,
wherein the analog-to-digital conversion circuit generates a second signal in response to the row driver performing binning on signals of the photo detectors included in the one pixel among the pixels, and
wherein the logic circuit generates an auto focus signal based on the first signal.

2. The camera module of claim 1, wherein the row lines comprise:
a first row line connected to the photo detectors of the first regions of the first sub-pixels of the pixels;
a second row line connected to the photo detectors of the second regions of the first sub-pixels of the pixels;
a third row line connected to the photo detectors of the first regions of the second sub-pixels of the pixels;
a fourth row line connected to the photo detectors of the second regions of the second sub-pixels of the pixels;
a fifth row line connected to the photo detectors of the first regions of the third subpixels of the pixels;
a sixth row line connected to the photo detectors of the second regions of the third sub-pixels of the pixels;
a seventh row line connected to the photo detectors of the first regions of the fourth sub-pixels of the pixels; and
an eighth row line connected to the photo detectors of the second regions of the fourth sub-pixels of the pixels.

3. The camera module of claim 1, wherein the row lines comprise:
a first row line connected to the photo detectors of the first regions of the first sub-pixels of the pixels;
a second row line connected to the photo detectors of the first regions of the second sub-pixels of the pixels;
a third row line connected to the photo detectors of the second regions of the first sub-pixels of the pixels and the photo detectors of the second regions of the second sub-pixels of the pixels;
a fourth row line connected to the photo detectors of the first regions of the third sub-pixels of the pixels and the photo detectors of the first regions of the fourth sub-pixels of the pixels; and
a fifth row line connected to the photo detectors of the second regions of the third sub-pixels of the pixels and the photo detectors of the second regions of the fourth sub-pixels of the pixels.

4. The camera module of claim 1, wherein the row lines comprise:
a first row line connected to the photo detectors of the first regions of the first sub-pixels of the pixels;
a second row line connected to the photo detectors of the first regions of the second sub-pixels of the pixels;
a third row line connected to the photo detectors of the second regions of the first sub-pixels of the pixels and the photo detectors of the second regions of the second sub-pixels of the pixels;
a fourth row line connected to the photo detectors of the first regions of the third sub-pixels of the pixels;
a fifth row line connected to the photo detectors of the first regions of the fourth sub-pixels of the pixels; and
a sixth row line connected to the photo detectors of the second regions of the third sub-pixels of the pixels and the photo detectors of the second regions of the fourth sub-pixels of the pixels.

5. The camera module of claim 1, wherein the row lines comprise:
a first row line connected to the photo detector of the first region of the first sub-pixel of a first pixel among the pixels and the photo detector of the second region of the first sub-pixel of a second pixel among the pixels;
a second row line connected to the photo detector of the second region of the first sub-pixel of the first pixel and the photo detector of the first region of the first sub-pixel of the second pixel;
a third row line connected to the photo detectors of the first regions of the second sub-pixels of the first pixel and the second pixel;
a fourth row line connected to the photo detectors of the second regions of the second sub-pixels of the first pixel and the second pixel;
a fifth row line connected to the photo detectors of the first regions of the third sub-pixels of the first pixel and the second pixel;
a sixth row line connected to the photo detectors of the second regions of the third sub-pixels of the first pixel and the second pixel;
a seventh row line connected to the photo detector of the first region of the fourth sub-pixel of the first pixel and the photo detector of the second region of the fourth sub-pixel of the second pixel; and
an eighth row line connected to the photo detector of the second region of the fourth sub-pixel of the first pixel and the photo detector of the first region of the fourth sub-pixel of the second pixel.

6. The camera module of claim 1, wherein the row driver activating the signals of half or less of the photo detectors included in the one pixel among the pixels includes the row driver activating a signal of one photo detector among the photo detectors included in the one pixel.

7. The camera module of claim 6, wherein the logic circuit generates the auto focus signal based on a value of the first signal and a value obtained by subtracting four times the value of the first signal from a value of the second signal.

8. The camera module of claim 1, wherein the row driver activating the signals of half or less of the photo detectors included in the one pixel among the pixels includes the row driver performing the binning on a signal of the photo detector of the first region of the first sub-pixel of the one pixel among the pixels and a signal of the photo detector of the first region of the third sub-pixel of the one pixel.

9. The camera module of claim 8, wherein the logic circuit generates the auto focus signal based on a value of the first signal and a value obtained by subtracting two times the value of the first signal from a value of the second signal.

10. The camera module of claim 1, wherein the row driver activating the signals of half or less of the photo detectors included in the one pixel among the pixels includes the row driver performing the binning on a signal of the photo detector of the first region of the first sub-pixel of the one pixel among the pixels and a signal of the photo detector of the first region of the second sub-pixel of the one pixel.

11. The camera module of claim 1, wherein the row driver activating the signals of half or less of the photo detectors included in the one pixel among the pixels includes the row driver performing the binning on a signal of the photo detector of the first region of the first sub-pixel of the one pixel among the pixels and a signal of the photo detector of the first region of the fourth sub-pixel of the one pixel.

12. The camera module of claim 1, wherein the row driver activating the signals of half or less of the photo detectors included in the one pixel among the pixels includes the row driver performing the binning on a signal of the photo detector of the first region of the first sub-pixel of the one pixel among the pixels and a signal of the photo detector of the first region of the fourth sub-pixel of the one pixel, and the row driver performing the binning on a signal of the photo detector of the second region of the first sub-pixel of another pixel among the pixels and a signal of the photo detector of the second region of the fourth sub-pixel of the one pixel.

13. The camera module of claim 12, wherein the logic circuit generates the auto focus signal based on a signal associated with the one pixel and a signal associated with the another pixel.

14. The camera module of claim 1, wherein the row lines comprise:
a first row line connected to the photo detectors of the first regions of the first sub-pixels of the pixels and the photo detectors of the first regions of the second sub-pixels of the pixels;
a second row line connected to the photo detectors of the second regions of the first sub-pixels of the pixels and the photo detectors of the second regions of the second sub-pixels of the pixels;
a third row line connected to the photo detectors of the first regions of the third sub-pixels of the pixels and the photo detectors of the first regions of the fourth sub-pixels of the pixels; and
a fourth row line connected to the photo detectors of the second regions of the third sub-pixels of the pixels and the photo detectors of the second regions of the fourth sub-pixels of the pixels.

15. The camera module of claim 1, wherein the analog-to-digital conversion circuit generates a third signal in response to the row driver performing the binning on the signals of the photo detectors included in the one pixel among the pixels, and
wherein, when the third signal is generated, the row driver increases a capacitance of a floating diffusion node of the pixels.

16. An operating method of a camera module, comprising:
receiving a signal from half or less of a plurality of photo detectors of one pixel among a plurality of pixels,
wherein the camera module comprises the plurality of pixels, the plurality of pixels comprises a plurality of sub-pixels, and each of the plurality of sub-pixels comprises a plurality of photo detectors; and
increasing the number of the photo detectors from which the signal is received in response to a level of the signal being smaller than a first threshold,
wherein auto focusing is performed based on the signal.

17. The method of claim 16, further comprising:
decreasing the number of the photo detectors from which the signal is received in response to the level of the signal being greater than a second threshold,
wherein a value of the second threshold is greater than a value of the first threshold.

18. The method of claim 17, further comprising:
maintaining the number of the photo detectors from which the signal is received in response to the level of the signal not being smaller than the first threshold and not being greater than the second threshold.

19. A camera module, comprising:
a first photo detector, a second photo detector, a third photo detector, and a fourth photo detector arranged in a first row;
a fifth photo detector, a sixth photo detector, a seventh photo detector, and an eighth photo detector arranged in a second row;
a row driver configured to connect half or less of the first to eighth photo detectors with a floating diffusion node in a first time interval, to connect the first to eighth photo detectors with the floating diffusion node in a second time interval, and to connect the first to eighth photo detectors with the floating diffusion node in a third time interval; and
an analog-to-digital conversion circuit configured to generate a first signal from the floating diffusion node in the first time interval, to generate a second signal from the floating diffusion node in the second time interval, and to generate a third signal from the floating diffusion node in the third time interval,
wherein the first signal is used in auto focusing.

20. The camera module of claim 19, wherein the number of the photo detectors connected by the row driver in the first time interval is variable depending on a level of the first signal.
